(19) United States
(12) Patent Application Publication
(10) Pub. No.: US 2025/0200236 A1
(43) Pub. Date: Jun. 19, 2025

(54) ELECTRONIC DEVICE AND METHOD FOR OPERATING THE SAME

(71) Applicant: SAMSUNG ELECTRONICS CO., LTD., Suwon-si (KR)

(72) Inventors: Changyoul LEE, Suwon-si (KR); Eunkyung YOO, Suwon-si (KR); Choonkyoung MOON, Suwon-si (KR); Kwanhee LEE, Suwon-si (KR); Yunsoo CHOI, Suwon-si (KR)

(73) Assignee: SAMSUNG ELECTRONICS CO., LTD., Suwon-si (KR)

(21) Appl. No.: 18/826,912

(22) Filed: Sep. 6, 2024

Related U.S. Application Data
(63) Continuation of application No. PCT/KR2024/013004, filed on Aug. 30, 2024.

(30) Foreign Application Priority Data
Dec. 18, 2023 (KR) 10-2023-0184684

(51) Int. Cl. G06F 30/13; G01J 1/42; H02S 50/00

(52) U.S. Cl. CPC G06F 30/13; G01J 1/4204; G01J 2001/4266; H02S 50/00

(57) ABSTRACT

An electronic device for solar power generation simulation obtains at least one information useable to perform a solar power generation simulation on a solar device having a solar power generation function, transmit the at least one information including the window transmission loss rate-related information to the server, receive result data of the solar power generation simulation from the server, and display the recommended placement area and information related to the solar power generation effect on the space or a map associated with the space, based on the result data. The information about the solar power generation effect is obtained based on the window transmission loss rate-related information.

### CROSS-REFERENCE TO RELATED APPLICATIONS

This application is a continuation application of International Application No. PCT/KR2024/013004 designating the United States, filed on Aug. 30, 2024, in the Korean Intellectual Property Receiving Office, which claims priority from Korean Patent Application No. 10-2023-0184684, filed on Dec. 18, 2023, in the Korean Intellectual Property Office, the disclosures of which are hereby incorporated by reference herein in their entireties.

### BACKGROUND

### Field

The disclosure relates to an electronic device and a method for operating the electronic device.

### Description of Related Art

Recently increased interest in clean energy leads to vigorous development of electronic devices (e.g., home appliances) with solar power generation functions. However, there is no way for the user to previously identify the solar power generation effect suitable for his or her residential space, causing it difficult to purchase an electronic device with a solar power generation function.

Therefore, a need exists for providing a new user experience by simulating the solar power generation effect and installable area of an electronic device with solar power generation function in a desired space using the user's electronic device (e.g., smartphone) and providing the same to the user.

### SUMMARY

According to an embodiment of the disclosure, an electronic device may comprise memory to store at least one instruction, and at least one processor connected to the memory and execute the at least one instruction stored in the memory. The at least one processor may be configured to: obtain at least one information useable to perform a solar power generation simulation relative to placement of a solar device having a solar power generation function in a space, the at least one information including window transmission loss rate-related information related to a loss rate of sunlight transmitted through a window in the space, transmit the at least one information including the window transmission loss rate-related information to the server, receive result data of the solar power generation simulation from the server, the result data including information about a recommended placement area of the solar device in the space and information about a solar power generation effect in the recommended placement area in the space, and provide the recommended placement area and information related to the solar power generation effect on the space or a map associated with the space, based on the result data. The information about the solar power generation effect is obtained based on the window transmission loss rate-related information.

According to an embodiment of the disclosure, a server may comprise memory to store at least one instruction, and at least one processor connected to the memory and execute the at least one instruction stored in the memory. The at least one processor may be configured to: receive, from an electronic device, at least information useable to perform a solar power generation simulation relative to placement of a solar device having a solar power generation function in a space, the at least one information including window transmission loss rate-related information related to a loss rate of sunlight transmitted through a window in the space, generate result data of the solar power generation simulation based on the at least one information, the result data including information about a recommended placement area of the solar device in the space and information about a solar power generation effect in the recommended placement area in the space, and transmit the result data of the solar power generation simulation to the electronic device. The information about the solar power generation effect is obtained based on the window transmission loss rate-related information.

According to an embodiment of the disclosure, an electronic device may comprise memory to store at least one instruction, and at least one processor connected to the memory and execute the at least one instruction stored in the memory. The at least one processor may be configured to: obtain at least one information useable to perform a solar power generation simulation on a solar device having a solar power generation function, the at least one information including window transmission loss rate-related information related to a loss rate of sunlight transmitted through a window in a space in which the solar device is to be located in association with the solar power generation simulation, generate result data of the solar power generation simulation based on the at least one information.

The result data may include information about a recommended placement area of the solar device and information about a solar power generation effect in the recommended placement area, and display the recommended placement area and information related to the solar power generation effect on the space or a map associated with the space, based on the result data. The information about the solar power generation effect may be obtained based on the window transmission loss rate-related information.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating an electronic device in a network environment according to various embodiments of the disclosure;

FIG. 2 is a view illustrating a structure of an example system according to an embodiment of the disclosure;

FIG. 3 is a flowchart illustrating a solar power generation simulation procedure according to an embodiment of the disclosure;

FIG. 4A is a flowchart illustrating operations of an electronic device in a solar power generation simulation procedure according to an embodiment of the disclosure;

FIG. 4B is a flowchart illustrating operations of a server in a solar power generation simulation procedure according to an embodiment of the disclosure;

FIG. 5 is a flowchart illustrating operations of an electronic device in a solar power generation simulation procedure according to an embodiment of the disclosure;

FIG. 6 is a flowchart illustrating an operation for obtaining recommended placement area information according to an embodiment of the disclosure;

FIG. 7 is a view illustrating a method for determining a common daylighting area for obtaining recommended placement area information according to an embodiment of the disclosure;

FIG. 8 is a view illustrating a method for determining the altitude and azimuth of the sun for determining a common daylighting area according to an embodiment of the disclosure;

FIG. 9 is a view illustrating a change in a common daylighting area according to a change in season according to an embodiment of the disclosure;

FIG. 10 is a flowchart illustrating an operation for determining a recommended placement area using surrounding building-related information according to an embodiment of the disclosure;

FIG. 11 is a view illustrating a shadow area generated by surrounding buildings according to an embodiment of the disclosure;

FIG. 12 is a flowchart illustrating an operation for determining a recommended placement area using surrounding building-related information according to an embodiment of the disclosure;

FIG. 13 is a flowchart illustrating an operation for determining a recommended placement area using solar device characteristic-related information according to an embodiment of the disclosure;

FIG. 14A is a view illustrating characteristics of a solar device according to an embodiment of the disclosure;

FIG. 14B is a view illustrating an example recommended placement area for a solar device having the characteristics of FIG. 14A according to an embodiment of the disclosure;

FIG. 15A is a view illustrating an example recommended placement area when one solar device is placed in a plurality of spaces according to an embodiment of the disclosure;

FIG. 15B is a view illustrating a recommended placement area when a plurality of solar devices are placed in a plurality of spaces according to an embodiment of the disclosure;

FIG. 16 is a view illustrating an example recommended placement area for a self-movable solar device according to an embodiment of the disclosure;

FIG. 17A is a view illustrating an example range-adjustable solar device according to an embodiment of the disclosure;

FIG. 17B is a view illustrating an example recommended placement area when a range-adjustable solar device alone is placed according to an embodiment of the disclosure;

FIG. 17C is a view illustrating an example recommended placement area when a range-adjustable solar device together with a movable solar device is placed according to an embodiment of the disclosure;

FIG. 17D is a view illustrating an example recommended placement area when a range-adjustable solar device together with a self-movable solar device is placed according to an embodiment of the disclosure;

FIG. 18 is a flowchart illustrating an operation for obtaining solar power generation effect information according to an embodiment of the disclosure;

FIG. 19 is a flowchart illustrating an operation for calculating a window transmission loss rate according to an embodiment of the disclosure;

FIG. 20 illustrates an example screen provided for an electronic device to calculate an illuminance value for calculating a window transmission loss rate according to an embodiment of the disclosure;

FIG. 21A is a flowchart illustrating a solar power generation simulation procedure according to an embodiment of the disclosure;

FIG. 21B is a flowchart illustrating a solar power generation simulation procedure according to an embodiment of the disclosure;

FIGS. 22A, 22B, 22C, 22D and 22E illustrate example screens provided for an electronic device to obtain information for a solar power generation simulation according to an embodiment of the disclosure;

FIGS. 23A. 23B and 23C illustrate example screens provided for an electronic device to show a result of solar power generation simulation according to an embodiment of the disclosure;

FIG. 24 illustrates an example screen for monitoring a solar power generation effect according to an embodiment of the disclosure;

FIG. 25A illustrates an example screen for setting information and a period to be displayed on a screen for monitoring a solar power generation effect according to an embodiment of the disclosure;

FIG. 25B illustrates an example screen for monitoring a solar power generation effect displayed according to the setting of FIG. 25A according to an embodiment of the disclosure;

FIGS. 26A and 26B illustrate an example screen for recommending a change in a placement position of a solar device according to an embodiment of the disclosure;

FIGS. 27A and 27B illustrate an example screen for recommending a change in a placement position of a solar device according to an embodiment of the disclosure;

FIG. 28 illustrates an example screen showing a recommended placement angle of a solar device according to an embodiment of the disclosure;

FIG. 29 is a view illustrating a method for calculating the amount of solar power generation in a rotatable solar device according to an embodiment of the disclosure;

FIG. 30 illustrates an example screen displaying an optimal placement area and solar power generation effect information for a space including a window having a first characteristic according to an embodiment of the disclosure;

FIG. 31 illustrates an example screen displaying an optimal placement area and solar power generation effect information for a space including a window having a second characteristic according to an embodiment of the disclosure;

FIG. 32 is a block diagram illustrating a server according to an embodiment of the disclosure; and

FIG. 33 is a block diagram illustrating a solar device according to an embodiment of the disclosure.

### DETAILED DESCRIPTION

Hereinafter, embodiments of the disclosure are described in detail with reference to the drawings so that those skilled in the art to which the disclosure pertains may easily practice the disclosure. However, the disclosure may be implemented in other various forms and is not limited to the embodiments set forth herein. The same or similar reference denotations may be used to refer to the same or similar elements throughout the specification and the drawings. Further, for clarity and brevity, no description is made of well-known functions and configurations in the drawings and relevant descriptions.

It should be appreciated that the blocks in each flowchart and combinations of the flowcharts may be performed by computer program instructions.

Further, each block may represent a module, segment, or part of a code including one or more executable instructions for executing a specified logical function(s). Further, it should also be noted that in some replacement embodiments, the functions mentioned in the blocks may occur in different orders. For example, two blocks that are consecutively shown may be performed substantially simultaneously or in a reverse order depending on corresponding functions.

As used herein, the term “unit” means a software element or a hardware element such as a field-programmable gate array (FPGA) or an application specific integrated circuit (ASIC). A unit plays a certain role. However, ‘unit’ is not limited to software or hardware. A ‘unit’ may be configured in a storage medium that may be addressed or may be configured to execute one or more packet processing devices. Accordingly, as an example, a ‘unit’ includes elements, such as software elements, object-oriented software elements, class elements, and task elements, processes, functions, attributes, procedures, subroutines, segments of program codes, drivers, firmware, microcodes, circuits, data, databases, data architectures, tables, arrays, and variables. Functions provided within the components and the ‘units’ may be combined into smaller numbers of components and ‘units’ or further separated into additional components and ‘units’. Further, an element or a ‘unit’ may be implemented to reproduce one or more central processing units (CPUs) in a device or a security multimedia card. According to embodiments, a “ . . . unit” may include one or more packet processing devices.

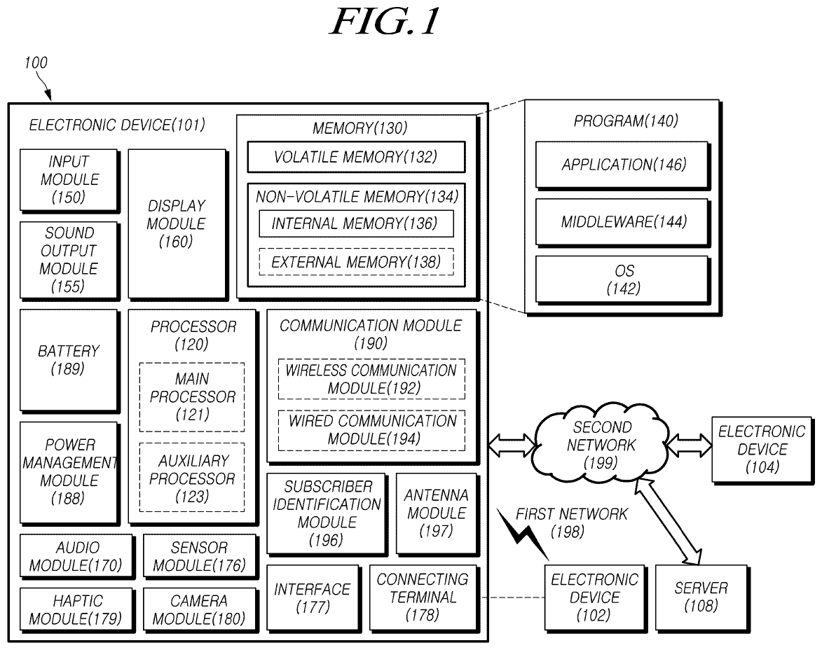

FIG. 1 is a block diagram illustrating an electronic device in a network environment according to various embodiments of the disclosure;

Referring to FIG. 1, the electronic device 101 in the network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. According to an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display 160 may include, for example, a display, a hologram device, or a projector and control circuitry to control a corresponding one of the display, hologram device, and projector. According to an embodiment, the display 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an accelerometer, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a communication module 192 (e.g., a cellular communication module, a short-range communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth™, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The communication module 192 may identify or authenticate the electronic device 101 in a communication network, such as the first network 198 or the second network 199, using subscriber information (e.g., international mobile subscriber identity (IMSI)) stored in the subscriber identification module 196.

The communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The communication module 192 may support a high-frequency band (e.g., the mmWave band) to achieve, e.g., a high data transmission rate. The communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The communication module 192 may support various requirements specified in the electronic device 101, an external electronic device (e.g., the electronic device 104), or a network system (e.g., the second network 199). According to an embodiment, the communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other parts (e.g., radio frequency integrated circuit (RFIC)) than the radiator may be further formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

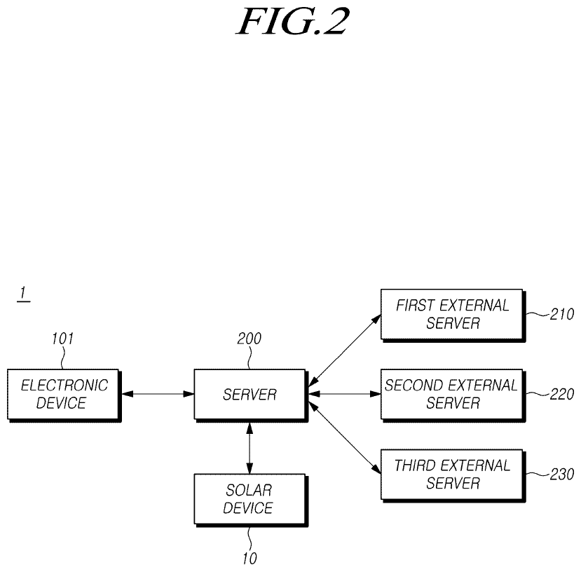

FIG. 2 is a view illustrating a structure of an example system according to an embodiment of the disclosure.

Referring to FIG. 2, a system 1 may include at least one solar device 10, an electronic device (e.g., the electronic device 101 of FIG. 1), a server 200, and/or at least one external server (e.g., the first external server 210, the second external server 220, and/or the third external server 230).

According to an embodiment, the system 1 may be a system for performing a solar power generation simulation. For example, each component of the system 1 may perform wired or wireless communication with each other to simulate solar power generation.

According to an embodiment, the solar power generation simulation may be performed to obtain recommended placement area information and/or solar power generation effect information for the solar device 10 as result data. For example, the solar power generation simulation may be performed to obtain indoor recommended placement area information and/or solar power generation effect information for the solar device 10 as result data. The result data of the solar power generation simulation may be generated by the electronic device 101 or the server 200. Through this solar power generation simulation, the user may identify the solar power generation effect suitable for the user's residential space situation in advance. This helps the user purchase an electronic device (e.g., an indoor home appliance) having a solar power generation function.

According to an embodiment, the electronic device 101 may perform solar power generation simulation using an application. The user may simply identify the solar power generation effect suitable for his/her residential space situation in advance using the application.

According to an embodiment, the recommended placement area information may include information about the recommended placement area of the solar device 10. The recommended placement area may be, e.g., an area recommended so that the solar device 10 is placed (or installed) in the space. The space may be, e.g., an indoor space (e.g., a room) including a window. The recommended placement area information may include, e.g., information about the location and/or size of the recommended placement area in the corresponding space. In the disclosure, the recommended placement area may be referred to as a recommended installation area, and the recommended placement area information may be referred to as recommended installation area information.

According to an embodiment, the solar power generation effect information may include information about the solar power generation effect in the corresponding space (or the recommended placement area). For example, the solar power generation effect information may include information about the amount of solar power generation and/or energy saving rate of the solar device 10 in the corresponding space. For example, the solar power generation effect information may include information about the amount of solar power generation and/or the energy saving rate of the solar device 10 in the recommended placement area in the corresponding space. The solar power generation effect information includes, e.g., information indicating the amount of solar power generation (e.g., annual solar power generation), information indicating the energy saving rate (e.g., annual energy saving rate), information indicating the amount of electricity bill savings according to the amount of solar power generation (e.g., annual solar power generation), information indicating the tree effect according to the amount of solar power generation (e.g., annual solar power generation), information indicating the polar bear effect according to the amount of solar power generation (e.g., annual solar power generation), information indicating the carbon reduction amount according to the amount of solar power generation (e.g., annual solar power generation), and/or information indicating a drivable time of the solar device 10 according to the amount of solar power generation (e.g., annual solar power generation).

According to an embodiment, the solar power generation simulation may be performed for each space for a selected solar device 10. For example, the solar power generation simulation may be performed for each space (e.g., bedroom, living room, etc.) in the corresponding place (e.g., house) for the selected solar device 10.

According to an embodiment, the solar power generation simulation may be performed for each solar device 10. For example, the solar power generation simulation may be performed for each space or for a specific space for each of the selected solar devices 10 (e.g., an air purifier, an air conditioner, a robot vacuum, etc.).

According to an embodiment, the solar device 10 may be an electronic device (e.g., a home appliance or an indoor home appliance) including a solar power generation function, which is the function of generating electricity using sunlight. The solar device 10 may be, e.g., an air purifier, an air conditioner, a movable TV, a vacuum cleaner, a robot vacuum, a clothing care device, or a smart blind (or intelligent blind) that includes a solar power generation function, but is not limited thereto.

According to an embodiment, the solar device 10 may include at least one solar panel (or module) for solar power generation. For example, the solar device 10 may generate electricity using sunlight irradiated to the solar panel. For example, the solar device 10 may generate electricity using sunlight that passes through the window and irradiated to the solar panel. The electricity generated by the solar power generation function may be stored in the battery of the solar device 10, and when the solar device 10 has an inverter function, electricity may be supplied to the home in real time through an outlet.

According to an embodiment, the solar device 10 may further perform a unique function (basic function) of the home appliance other than the solar power generation function. For example, when the solar device 10 is an air purifier having a solar power generation function, the solar device 10 may further perform an air purifying function in addition to the solar power generation function.

According to an embodiment, the solar device 10 may transmit various information about the solar device 10 (e.g., location information about the solar device 10, setting information set by the user on the solar device 10, operation state information and/or operating environment information about the solar device 10) to the server 200 through a network. Transmission of such information may occur when a request is received from the server 200, when a specific event occurs in the solar device 10, and may occur periodically, or in real-time.

According to an embodiment, the solar device 10 may obtain information from the server 200 through the network. For example, the solar device 10 may obtain a command or data for changing settings or controlling driving of one or more components included in the solar device 10 from the server 200, and may be operable based on the obtained command or data.

According to an embodiment, the solar device 10 may obtain various information available in connection with the operation of the solar device 10 from the server 200. The solar device 10 may provide the information obtained from the server 200 to the user in various forms such as visual and auditory forms.

According to an embodiment, the electronic device 101 may communicate with the solar device 10 and/or a server (e.g., the server 200 or at least one external server 210, 220, and 230) using wireless or wired communication. For example, the electronic device 101 may obtain at least one information for performing the solar power generation simulation and transmit the obtained at least one information to the server 200, and may receive result data of the solar power generation simulation from the server 200. For example, the electronic device 101 may obtain at least one information for performing solar power generation simulation, and may generate result data of the solar power generation simulation based on the at least one information. The result data of the solar power generation simulation may include recommended placement area information and/or solar power generation effect information. For example, the electronic device 101 is configured to transmit a command, request, or data for controlling the solar device 10 to the solar device 10 or the server 200. For example, the electronic device 101 may transmit a command, a request, or data for controlling the solar device 10, based on direct communication. For example, the electronic device 101 may transmit a command, a request, or data for controlling the solar device 10 over the network.

According to an embodiment, the electronic device 101 may obtain information (e.g., information for solar power generation simulation) from at least one external server 210, 220, or 230 through the network or from at least one external server 210, 220, or 230 through the server 200. For example, the electronic device 101 may obtain solar device characteristic-related information from the first external server 210 (e.g., a product data server) or from the first external server 210 through the server 200. For example, the electronic device 101 may obtain sunlight-related information from the second external server 220 (e.g., a weather data server) or from the second external server 220 through the server 200. For example, the electronic device 101 may obtain surrounding building-related information from the third external server 230 (e.g., a building data server) or from the third external server 230 through the server 200.

According to an embodiment, the electronic device 101 may be a stationary or mobile terminal implemented as a computer device. The electronic device 101 may include, e.g., but not limited to, a smart phone, a mobile phone, a navigation system, a desktop computer, a laptop computer, a tablet computer, a wearable device, an IoT device, and/or an XR device.

According to an embodiment, the server 200 may comprise a computer device or two or more computer devices that provide commands, codes, files, content, and/or services through the network with other devices.

According to an embodiment, the server 200 may register and manage information about one or more solar devices 10. For example, each solar device 10 may register identification information such as a serial number or a MAC address allocated to the corresponding solar device 10 to the server 200.

According to an embodiment, the server 200 may communicate with the solar device 10, the electronic device 101, and/or the at least one external server 210, 220, and 230 over the network. For example, the server 200 may receive at least one information for the solar power generation simulation from the electronic device 101, generate result data of the solar power generation simulation based on the at least one information, and transmit the generated result data of the solar power generation simulation to the electronic device 101.

According to an embodiment, the server 200 may obtain information (e.g., information for simulation of solar power generation) from the at least one external server 210, 220, and 230 through the network. For example, the server 200 may obtain solar device characteristic-related information from the first external server 210 (e.g., a product data server). For example, the server 200 may obtain sunlight-related information from the second external server 220 (e.g., a weather data server). For example, the server 200 may obtain surrounding building-related information from the third external server 230 (e.g., building data server).

According to an embodiment, the server 200 may generate control information for the solar device 10, based on information obtained from the solar device 10, the electronic device 101, and/or the at least one external server 210, 220, and 230. The server 200 may transmit the generated control information to the solar device 10 and/or the electronic device 101.

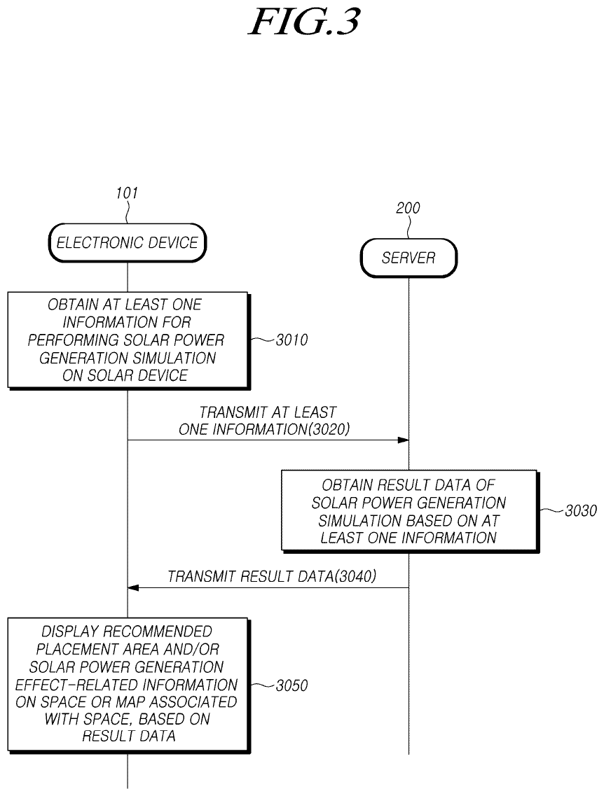

FIG. 3 is a flowchart illustrating a solar power generation simulation procedure according to an embodiment of the disclosure.

In operation 3010, the electronic device 101 may obtain at least one information (hereinafter, simulation-related information) for performing a solar power generation simulation on a solar device (e.g., the solar device 10 of FIG. 2).

According to an embodiment, the solar power generation simulation may be performed to obtain recommended placement area information and/or solar power generation effect information for the solar device as result data.

According to an embodiment, the solar power generation simulation may be performed for each space for a selected solar device. For example, the solar power generation simulation may be performed for each space (e.g., bedroom, living room, etc.) in the corresponding place (e.g., house) for the selected solar device.

According to an embodiment, the solar power generation simulation may be performed for each solar device. For example, the solar power generation simulation may be performed for each space or for a specific space for each of the selected solar devices (e.g., an air purifier, an air conditioner, a robot vacuum, etc.).

According to an embodiment, at least one simulation-related information may be obtained based on a user input of the electronic device 101, data obtained by at least one component (e.g., a sensor (e.g., a GPS, an illuminance sensor, a direction sensor, etc.) or a camera) of the electronic device 101, and/or data received from at least one server (e.g., the server 210, 220, or 230).

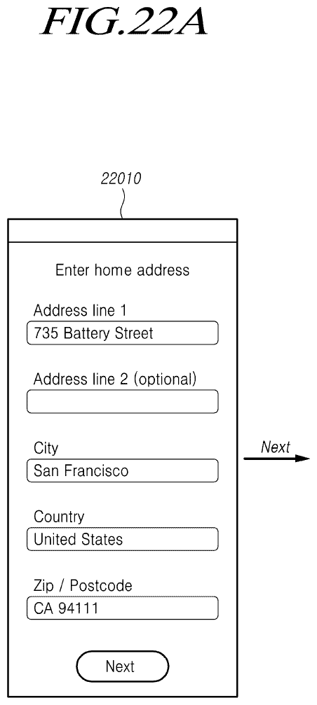

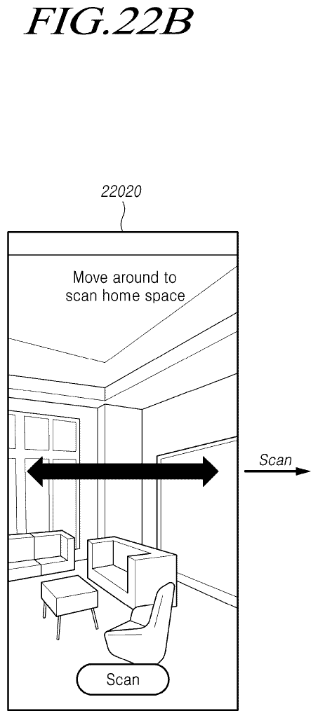

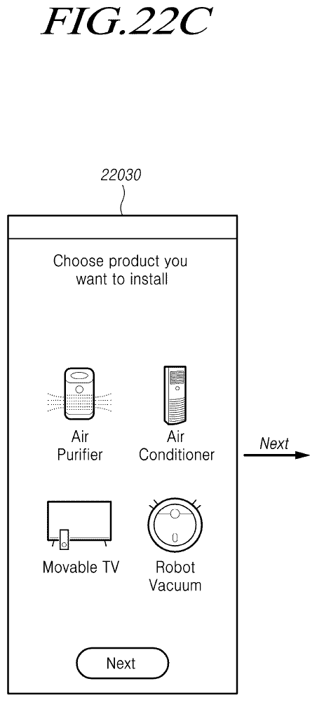

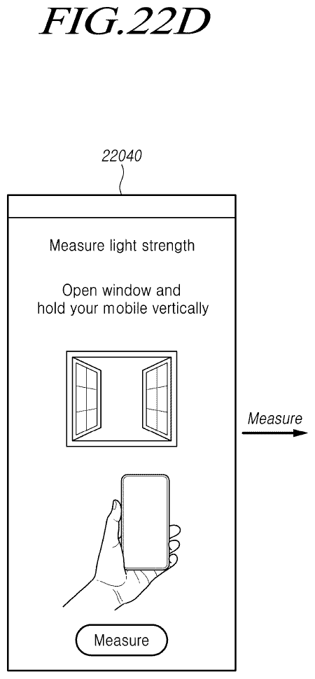

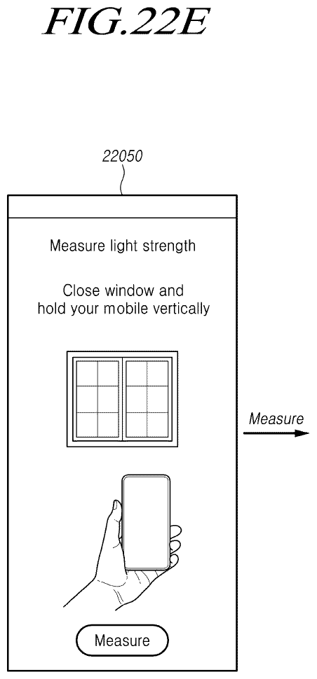

According to an embodiment, the at least one simulation-related information may include location-related information, space-related information, window transmission loss rate-related information, and/or solar device-related information. An example of a user interface (or screen) provided by the electronic device 101 to obtain at least one simulation-related information is described below with reference to FIGS. 22A to 22E.

According to an embodiment, the location-related information may include information related to the location of a space (e.g., an indoor space including a window) or a place (e.g., a house) including the space. The location-related information may include, but is not limited to, e.g., the location of the corresponding space or place (e.g., latitude or longitude), the height (e.g., altitude) of the corresponding space or place, and/or information about the address (e.g., home address) of the corresponding space or place (hereinafter, address information).

According to an embodiment, the space-related information may include information related to at least one space (e.g., a bedroom, a living room) and/or an object (e.g., a window) in the at least one space. For example, the space-related information may include three-dimensional (3D) space information and/or information about the object in the space for at least one space.

According to an embodiment, the 3D space information may include information related to the configuration, shape, state, characteristic, and/or attribute of the corresponding space. The 3D space information may be obtained, e.g., through 3D scanning of the corresponding space. For example, the 3D space information may be obtained through 3D scanning of the space using the electronic device 101. For example, the 3D space information may be obtained through 3D scanning of the space using a camera, a depth camera, a lidar, and/or a time of flight (ToF) measurement component (e.g., a UWB communication module, a Bluetooth (BT) communication module) of the electronic device 101.

According to an embodiment, the information about the object in the space may include information related to the configuration, shape, state, characteristic, and/or attribute of at least one object (e.g., the window) in the corresponding space. For example, the information about the object in the space may include information about the type, location, height, size, and/or direction of the object in the corresponding space. For example, when a window is included as an object in the space, the information about the object in the space may include window information, and the window information may include information about the type, characteristic, location, height, horizontal length and vertical length, size, and/or direction (e.g., the azimuth angle of the window) of the corresponding window in the corresponding space. The information about the object in the space may be obtained, e.g., by photographing and/or sensing the object in the space. For example, the information about the object in the space may be obtained through photographing and/or sensing of the object in the space using the electronic device. For example, the information about the object in the space may be obtained based on the 3D space information. In the disclosure, for convenience of description, an example in which a window is an object in a space through which sunlight is transmitted is described, but the disclosure is not limited thereto. For example, various embodiments of the disclosure may be applied to various types of objects through which sunlight is transmitted.

According to an embodiment, the window transmission loss rate-related information may include information related to the loss rate generated when sunlight passes through the window. For example, the window transmission loss rate-related information may include transmission loss rate information indicating the loss rate generated when sunlight passes through the window in the corresponding space. For example, the window transmission loss rate-related information may include illuminance information used to calculate the loss rate generated when sunlight passes through the window in the corresponding space.

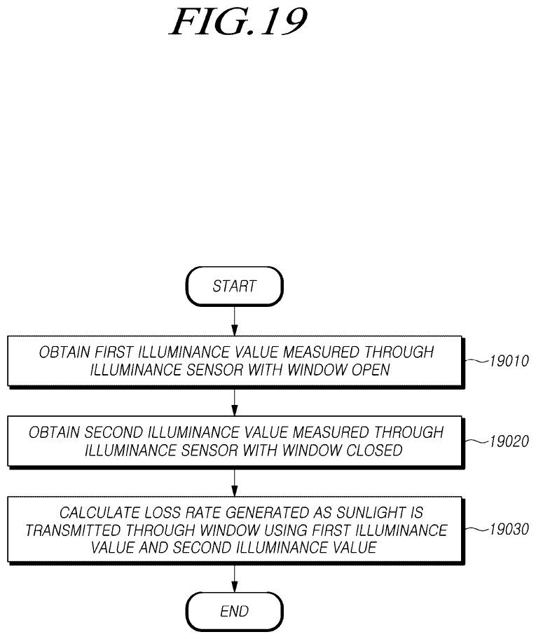

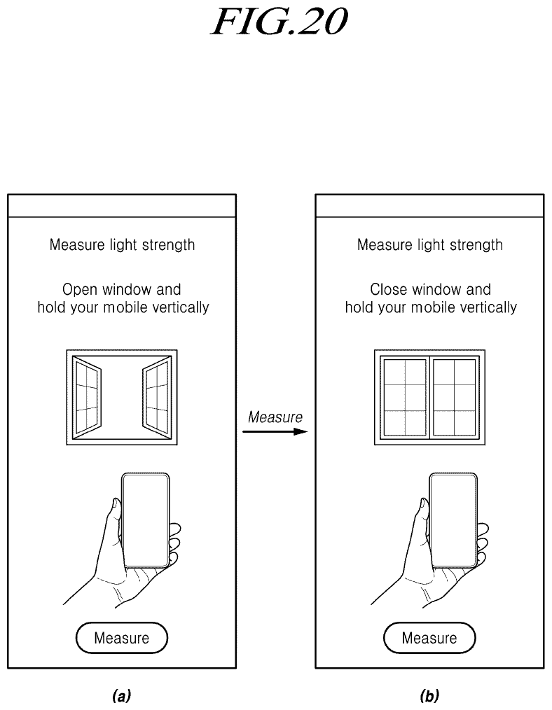

According to an embodiment, the illuminance information may include a first illuminance value obtained through the illuminance sensor while the window is opened and/or a second illuminance value obtained through the illuminance sensor while the window is closed. The illuminance information may be obtained by, e.g., the electronic device 101 (or the illuminance sensor of the electronic device 101). For example, when the first illuminance value is 100 Lux and the second illuminance value is 64.5 Lux, the window transmission loss rate corresponds to 0.645 (or 64.5%). An embodiment associated with the window transmission loss rate is described below, e.g., with reference to FIGS. 19 to 20.

According to an embodiment, the solar device-related information may include information for identifying the solar device where the solar power generation simulation is performed. For example, the solar device-related information may include information about the ID, the product name, and/or the model name for identifying the solar device.

In operation 3020, the electronic device 101 may transmit the obtained at least one information (simulation-related information) to the server 200. The server 200 may receive (or obtain) at least one simulation-related information.

In operation 3030, the server 200 may obtain (or generate) result data of the solar power generation simulation based on at least one information (simulation-related information).

According to an embodiment, the result data of the solar power generation simulation may include recommended placement area information and/or solar power generation effect information for the solar device.

According to an embodiment, the recommended placement area information may include information about the recommended placement area of the solar device. The recommended placement area may be, e.g., an area recommended so that the solar device is placed (or installed) in the space. The space may be, e.g., an indoor space (e.g., a room) including a window. The recommended placement area information may include, e.g., information about the location and/or size of the recommended placement area in the corresponding space.

According to an embodiment, the solar power generation effect information may include information about the solar power generation effect in the corresponding space (or the recommended placement area). For example, the solar power generation effect information may include information about the amount of solar power generation and/or energy saving rate of the solar device in the corresponding space. For example, the solar power generation effect information may include information about the amount of solar power generation and/or the energy saving rate of the solar device in the recommended placement area in the corresponding space. The solar power generation effect information includes, e.g., information indicating the amount of solar power generation (e.g., annual solar power generation), information indicating the energy saving rate (e.g., annual energy saving rate), information indicating the amount of electricity bill savings according to the amount of solar power generation (e.g., annual solar power generation), information indicating the tree effect according to the amount of solar power generation (e.g., annual solar power generation), information indicating the polar bear effect according to the amount of solar power generation (e.g., annual solar power generation), information indicating the carbon reduction amount according to the amount of solar power generation (e.g., annual solar power generation), and/or information indicating a drivable time of the solar device 10 according to the amount of solar power generation.

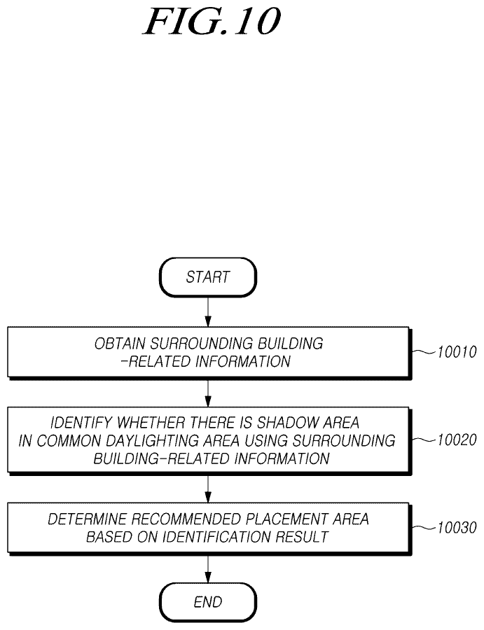

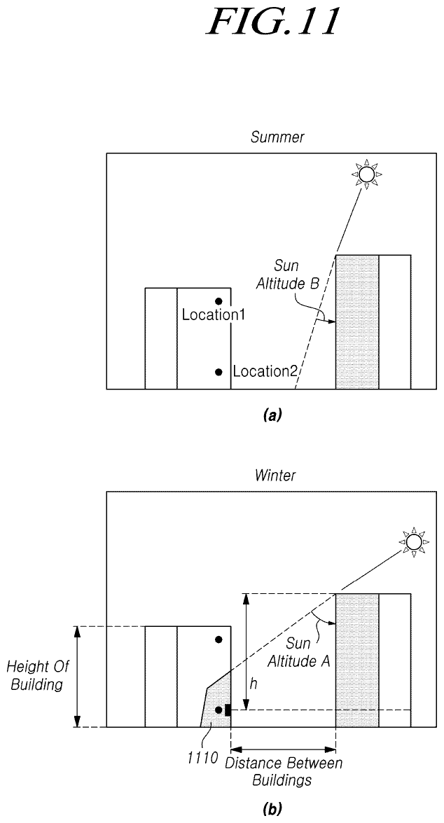

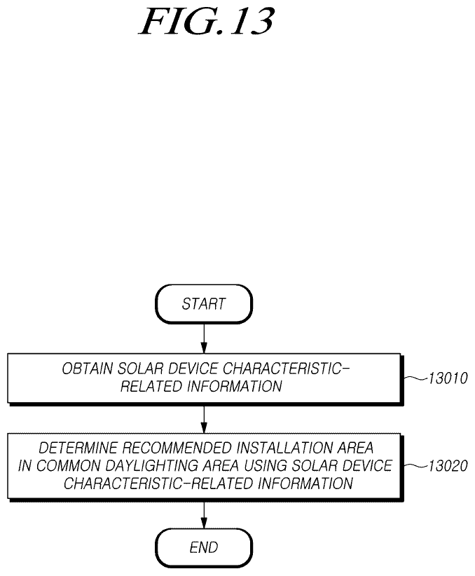

According to an embodiment, the server 200 may obtain (or generate) the recommended placement area information based on location-related information, space-related information, and/or solar device-related information included in at least one simulation-related information. For example, the server 200 may obtain the recommended placement area information using the sunlight-related information obtained based on the space-related information and the location-related information. A related embodiment is described below with reference to FIGS. 6 to 9. For example, the server 200 may obtain the recommended placement area information using the sunlight-related information obtained based on the space-related information and the location-related information, and the surrounding building-related information obtained based on the location-related information. A related embodiment is described below with reference to FIGS. 10 to 12. For example, the server 200 may obtain the recommended placement area information using the sunlight-related information obtained based on the space-related information and the location-related information, and the solar device characteristic-related information obtained based on the solar device-related information. Embodiments of the disclosure are described below with reference to FIGS. 13 to 17D. For example, the server 200 may obtain the recommended placement area information using the sunlight-related information obtained based on the space-related information and the location-related information, the surrounding building-related information obtained based on the location-related information, and the solar device characteristic-related information obtained based on the solar device-related information.

According to an embodiment, the sunlight-related information may include information about the position of the sun (e.g., the altitude and/or azimuth of the sun) and/or the solar irradiation in the corresponding space (or place). The information about the altitude of the sun (hereinafter, referred to as altitude information) may include, e.g., information indicating the altitude of the sun (e.g., the meridian altitude) at a specific time point (e.g., a specific day (e.g., the summer solstice (2023 Jun. 21))). The information about the azimuth of the sun (hereinafter, referred to as azimuth information) may include, e.g., information indicating the azimuth of the sun for the start time (e.g., 10 o'clock) of the effective daylighting time (e.g., 10 o'clock to 3 o'clock) at a specific time point (e.g., a specific day (e.g., the summer solstice (2023 Jun. 21))) and information indicating the azimuth of the sun for the end time (e.g., 3 o'clock). The information about the solar irradiation (hereinafter, solar irradiation information) may include, e.g., information indicating the solar irradiation (e.g., annual solar irradiation).

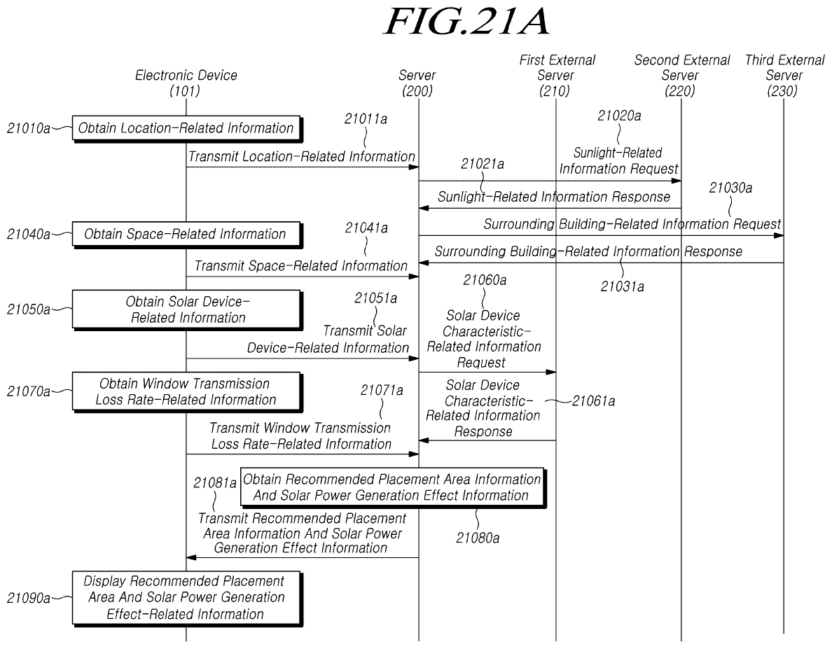

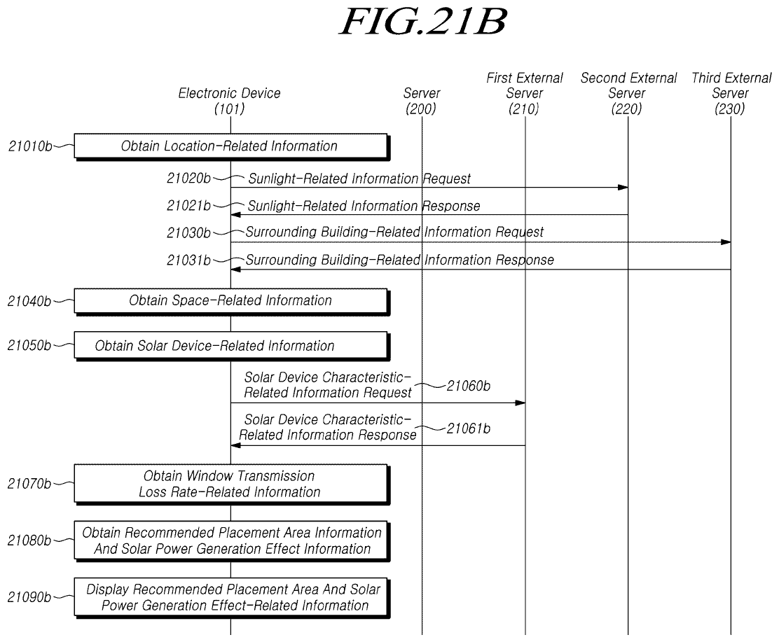

According to an embodiment, the server 200 may obtain sunlight-related information from an external server (e.g., a weather data server (e.g., the second external server 220 of FIG. 2) based on the location-related information. For example, the server may transmit a sunlight-related information request message including location-related information to the external server, and the external server may transmit a sunlight-related information response message including sunlight-related information corresponding to the location-related information (e.g., the corresponding space or place) to the server in response to the sunlight-related information request message. A related embodiment is described below with reference to FIG. 21A.

According to an embodiment, the surrounding building-related information may include information about the height of at least one building around the building including the corresponding space, the distance to the building, the placement, and/or the shadow. As an example, the surrounding building-related information may include information about the height of each surrounding building located around the corresponding building, the distance to the corresponding building, the placement, and/or the shadow.

According to an embodiment, the server 200 may obtain surrounding building-related information from an external server (e.g., a building data server (e.g., the third external server 230 of FIG. 2) based on the location-related information. For example, the server may transmit a surrounding building-related information request message including location-related information to an external server, and the external server may transmit a surrounding building-related information response message including surrounding building-related information corresponding to location-related information (e.g., a corresponding space or place) to the server in response to the surrounding building-related information request message. A related embodiment is described below with reference to FIG. 21A.

According to an embodiment, the solar device characteristic-related information may include information about the size of the solar device, the number, size, power generation efficiency, installation location (or placement location) and angle of the solar cell panels included in (or attached to) the solar device, panel angle loss rate, mobility, power consumption (e.g., annual power consumption), installation interval (or placement interval), and/or operation characteristics (e.g., air flow for an air purifier) of the solar device. The information about the mobility of the solar device may include, e.g., information about whether the solar device is a self-movable device (e.g., a robot vacuum) capable of moving (e.g., changing the location/direction) by itself, a movable device (e.g., an air purifier) capable of being moved by the user, a range-adjustable device (e.g., a smart blind) capable of changing the range up/down or left/right, or a fixed device (e.g., an air conditioner). In the disclosure, the panel angle loss rate may be referred to as a module angle loss rate.

According to an embodiment, the server 200 may obtain the solar device characteristic-related information from an external server (e.g., a product data server (e.g., the first external server 210 of FIG. 2) based on the solar device-related information. For example, the server may transmit a solar device characteristic-related information request message including solar device-related information to an external server, and the external server may transmit a solar device characteristic-related information response message including solar device characteristic-related information corresponding to solar device-related information (e.g., a corresponding solar device) to the server in response to the solar device characteristic-related information request message. A related embodiment is described below with reference to FIG. 21A.

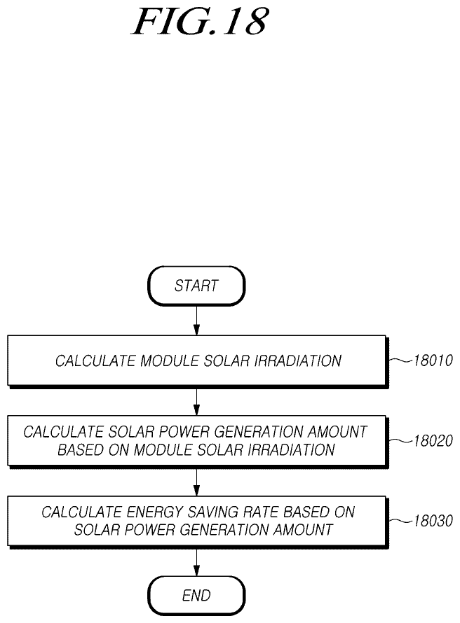

According to an embodiment, the server 200 may obtain solar power generation effect information based on location-related information, space-related information, window transmission loss rate-related information, and solar device-related information included in at least one simulation-related information. For example, the server 200 may obtain solar power generation effect information using sunlight-related information obtained based on space-related information, window transmission loss rate-related information, location-related information, and solar device characteristic-related information obtained based on solar device-related information. A related embodiment is described below with reference to FIGS. 18 to 20.

In operation 3040, the server may transmit the result data of the solar power generation simulation to the electronic device 101. The electronic device 101 may receive the result data from the server 200. According to an embodiment, the result data may include recommended placement area information and/or solar power generation effect information for the solar device.

In operation 3050, based on the result data of the solar power generation simulation, the electronic device 101 may display the recommended placement area and/or solar power generation effect-related information for the solar device on a space or a map associated with the space. According to an embodiment, the electronic device 101 may display the recommended placement area and/or solar power generation effect-related information for the solar device on the space or the map associated with the space, using the recommended placement area and/or solar power generation effect-related information.

For example, the electronic device 101 may display first information related to the solar power generation effect and the recommended placement area for the solar device on the space or the map associated with the space using the recommended placement area-related information and the solar power generation effect-related information.

According to an embodiment, the first information related to the solar power generation effect may include information indicating the amount of solar power generation (e.g., annual solar power generation) and/or information indicating the energy saving rate (e.g., annual energy saving rate) included in the solar power generation effect information. In the disclosure, the first information related to the solar power generation effect may be referred to as basic information related to the solar power generation effect.

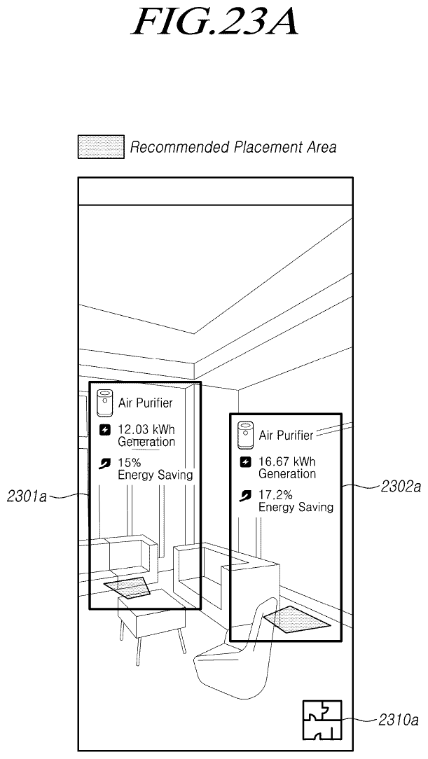

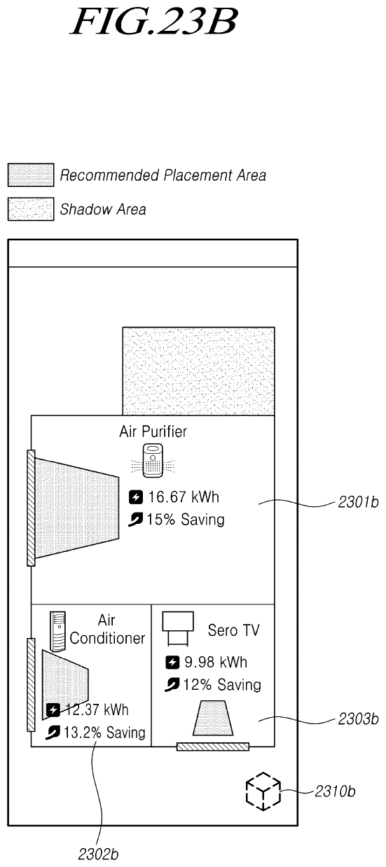

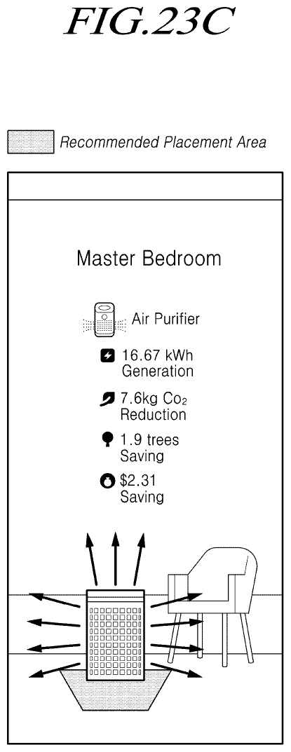

According to an embodiment, the electronic device 101 may display the recommended placement area obtained using the recommended placement area information and the first information related to the solar power generation effect obtained using the solar power generation effect information on the space. For example, the electronic device 101 may display an augmented image including the recommended placement area obtained using the recommended placement area information and/or the first information related to the solar power generation effect obtained using the solar power generation effect information in a real space (or a real environment including the corresponding space). For example, the electronic device 101 may display the augmented image including the recommended placement area obtained using the recommended placement area information and the first information related to the solar power generation effect obtained using the solar power generation effect information about an image related to the corresponding space. The image associated with the space may be, e.g., an image (e.g., a 3D image) of the corresponding space generated based on the space-related information (e.g., 3D space information) or an image of the corresponding space captured in real time by the electronic device. In the disclosure, the screen (or view) (e.g., the screen of FIG. 23A) where the recommended placement area and first information related to the solar power generation effect are displayed on the space or the image related to the space may be referred to as an AR view or a basic AR view. In the disclosure, a screen (or view) (e.g., the screen of FIG. 23B) where the recommended placement area and the first information related to the solar power generation effect are displayed on the map related to the space may be referred to as a map view.

According to an embodiment, the map associated with the space may be a map of the place (e.g., the house) including the corresponding space (e.g., the room) generated based on the space-related information (e.g., 3D space information). The map may further include space(s) other than the corresponding space.

According to an embodiment, the electronic device 101 may display the second information related to the solar power generation effect on the space, based on identification of an event (or a display mode switch event) for displaying detailed information about the solar power generation effect in a state in which the first information related to the solar power generation effect is displayed on the space or the map (or while the first information related to the solar power generation effect is displayed on the space or the map). For example, the electronic device 101 may display an augmented image including the second information related to the solar power generation effect obtained using the solar power generation effect information on a real space (or a real environment including the corresponding space). For example, the electronic device 101 may display an augmented image including the second information related to the solar power generation effect obtained using the solar power generation effect information on the image related to the corresponding space. The image associated with the space may be, e.g., an image (e.g., a 3D image) of the corresponding space generated based on the space-related information (e.g., 3D space information) or an image of the corresponding space captured in real time by the electronic device 101. According to an embodiment, the real environment (or the image associated with the space) associated with the space where the second information associated with the solar power generation effect is displayed may be different from the real environment (or the image associated with the space) associated with the space where the first information associated with the solar power generation effect is displayed.

According to an embodiment, the second information related to the solar power generation effect may include information different from the first information related to the solar power generation effect. For example, the second information related to the solar power generation effect may include more detailed or larger amounts of information than the first information related to the solar power generation effect. As an example, the second information related to the solar power generation effect may include information indicating the amount of solar power generation (e.g., annual solar power generation) included in the solar power generation effect information, information indicating the tree effect according to the amount of solar power generation (e.g., annual solar power generation), information indicating the carbon reduction amount according to the amount of solar power generation (e.g., annual solar power generation), and/or information indicating cost savings according to the amount of solar power generation (e.g., annual solar power generation). In the disclosure, the second information related to the solar power generation effect may be referred to as detailed information related to the solar power generation effect. In the disclosure, the screen (or view) (e.g., the screen of FIG. 23C) where the recommended placement area and second information related to the solar power generation effect are displayed on the space or the image associated with the space may be referred to as a detailed AR view.

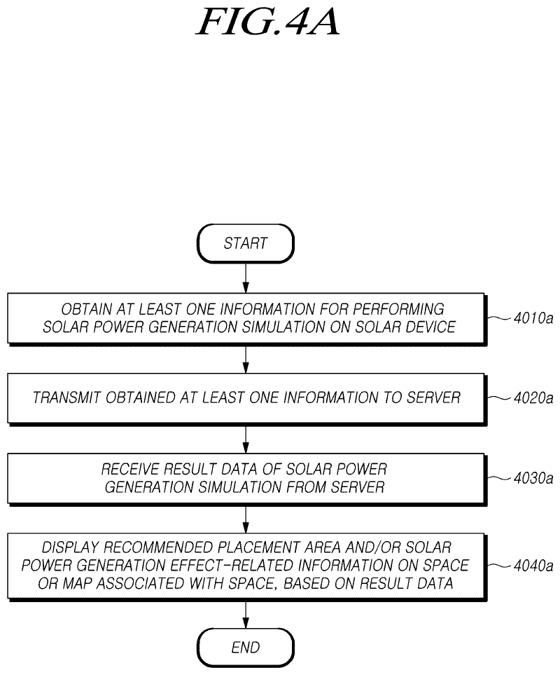

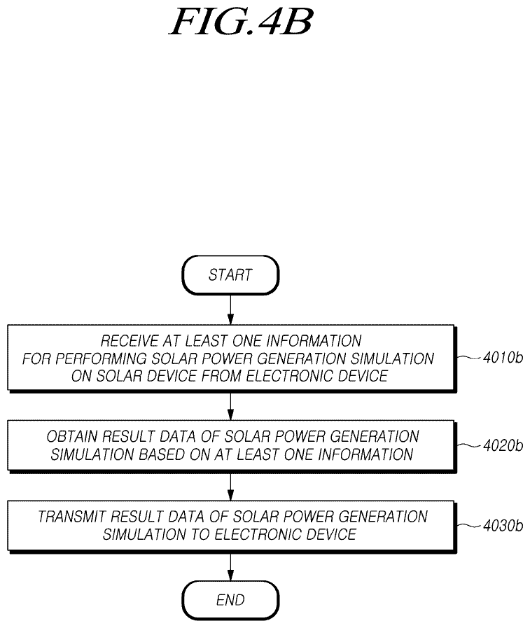

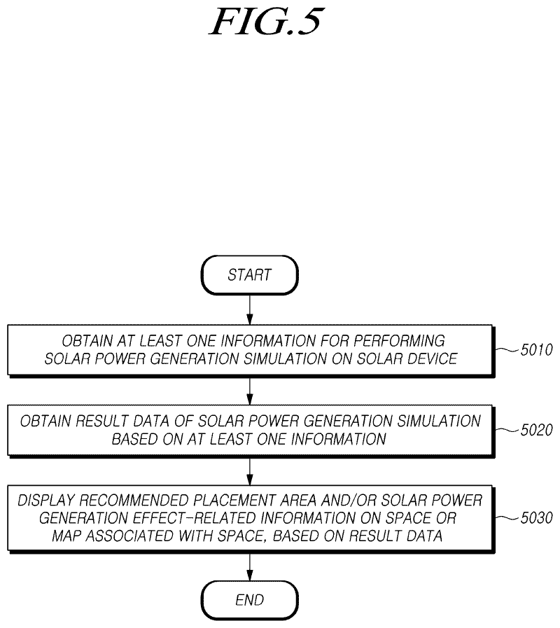

FIG. 4A is a flowchart illustrating operations of an electronic device in a solar power generation simulation procedure according to an embodiment of the disclosure.

The solar power generation simulation procedure of FIG. 4A may correspond to the solar power generation simulation procedure of FIG. 3.

Referring to FIG. 4A, in operation 4010a, an electronic device (e.g., the electronic device 101 of FIGS. 1, 2, and 3) may obtain at least one information (simulation-related information) for performing solar power generation simulation on a solar device (e.g., the solar device 10 of FIG. 2). For the description of operation 4010a, a reference may be made to the description of operation 3010 of FIG. 3. Therefore, no duplicate description is given.

In operation 4020a, the electronic device 101 may transmit the obtained at least one information (simulation-related information) to a server (e.g., the server 200 of FIGS. 2 and 3). For the description of operation 4020a, a reference may be made to the description of operation 3020 of FIG. 3. Therefore, no duplicate description is given.

In operation 4030a, the electronic device 101 may receive the result data of the solar power generation simulation from the server 200. For the description of operation 4030a, the description of operation 3030 and operation 3040 of FIG. 3 may be referred to. No duplicate description thereof is presented below.

In operation 4040a, based on the result data of the solar power generation simulation, the electronic device 101 may display a recommended placement area and/or solar power generation effect-related information for the solar device on the space or the map associated with the space. For the description of operation 4040a, a reference may be made to the description of operation 3050 of FIG. 3. Therefore, no duplicate description is given.

FIG. 4B is a flowchart illustrating operations of a server in a solar power generation simulation procedure according to an embodiment of the disclosure.

The solar power generation simulation procedure of FIG. 4B may correspond to the solar power generation simulation procedure of FIG. 3.

Referring to FIG. 4B, in operation 4010b, a server (e.g., the server 200 of FIGS. 2 and 3) may receive at least information (simulation-related information) from an electronic device (e.g., the electronic device 101 of FIGS. 1, 2, and 3). For the description of operation 4010b, the description of operation 3010 and operation 3020 of FIG. 3 may be referred to. No duplicate description thereof is presented below.

In operation 4020b, the server 200 may obtain (or generate) result data of the solar power generation simulation, based on at least one information (simulation-related information). For the description of operation 4020b, the description of operation 3030 of FIG. 3 may be referred to. No duplicate description thereof is presented below.

In operation 4030b, the server 200 may transmit the result data of the solar power generation simulation to the electronic device 101. For the description of operation 4030b, the description of operations 3040 and 3050 of FIG. 3 may be referred to. No duplicate description thereof is presented below.

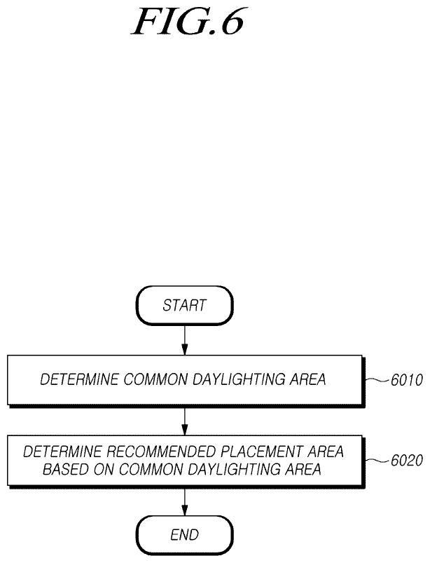

Meanwhile, in the embodiments of FIGS. 3 to 4B described above, it is exemplified that the result data of the solar power generation simulation is generated by the server 200, but the disclosure is not limited thereto. For example, the result data of the solar power generation simulation may be generated by the electronic device 101. Hereinafter, operations of an electronic device in a solar power generation simulation procedure where result data of a solar power generation simulation is generated by the electronic device 101 are described with reference to FIG. 5.

FIG. 5 is a flowchart illustrating operations of an electronic device in a solar power generation simulation procedure according to an embodiment of the disclosure.

In the solar power generation simulation procedure of FIG. 5, unlike the solar power generation simulation procedure of FIG. 3, result data of the solar power generation simulation may be generated by the electronic device 101.

Referring to FIG. 5, in operation 5010, an electronic device (e.g., the electronic device 101 of FIGS. 1, 2, and 3) may obtain at least one information (simulation-related information) for performing a solar power generation simulation on a solar device (e.g., the solar device 10 of FIG. 2). For the description of operation 5010, a reference may be made to the description of operation 3010 of FIG. 3. Therefore, no duplicate description is given.

In operation 5020, the electronic device 101 may obtain (or generate) result data of the solar power generation simulation, based on at least one information (simulation-related information). For the description of operation 5020, a reference may be made to the description of operation 3030 of FIG. 3. Therefore, no duplicate description is given.

According to an embodiment, the electronic device 101 may obtain (or generate) recommended placement area information, based on location-related information, space-related information, and/or solar device-related information included in at least one simulation-related information. For example, the electronic device 101 may obtain the recommended placement area information using the sunlight-related information obtained based on the space-related information and the location-related information. A related embodiment is described below with reference to FIGS. 6 to 9. For example, the electronic device 101 may obtain the recommended placement area information using the sunlight-related information obtained based on the space-related information and the location-related information and the surrounding building-related information obtained based on the location-related information. A related embodiment is described below with reference to FIGS. 10 to 12. For example, the electronic device 101 may obtain the recommended placement area information using the sunlight-related information obtained based on the space-related information and the location-related information, and the solar device characteristic-related information obtained based on the solar device-related information. Embodiments of the disclosure are described below with reference to FIGS. 13 to 17D. For example, the electronic device 101 may obtain the recommended placement area information using the sunlight-related information obtained based on the space-related information and the location-related information, the surrounding building-related information obtained based on the location-related information, and the solar device characteristic-related information obtained based on the solar device-related information.

According to an embodiment, the electronic device 101 may obtain sunlight-related information from an external server (e.g., a weather data server (e.g., the second external server 220 of FIG. 2) based on the location-related information. For example, the electronic device 101 may transmit a sunlight-related information request message including location-related information to the external server, and the external server may transmit a sunlight-related information response message including sunlight-related information corresponding to the location-related information (e.g., the corresponding space or place) to the electronic device 101 in response to the sunlight-related information request message. A related embodiment is described below with reference to FIG. 21B.

According to an embodiment, the electronic device 101 may obtain surrounding building-related information from an external server (e.g., a building data server (e.g., the third external server 230 of FIG. 2) based on the location-related information. For example, the electronic device 101 may transmit a surrounding building-related information request message including location-related information to an external server, and the external server may transmit a surrounding building-related information response message including surrounding building-related information corresponding to location-related information (e.g., a corresponding space or place) to the electronic device 101 in response to the surrounding building-related information request message. A related embodiment is described below with reference to FIG. 21B.

According to an embodiment, the electronic device 101 may obtain the solar device characteristic-related information from an external server (e.g., a product data server (e.g., the first external server 210 of FIG. 2) based on the solar device-related information. For example, the electronic device 101 may transmit a solar device characteristic-related information request message including solar device-related information to an external server, and the external server may transmit a solar device characteristic-related information response message including solar device characteristic-related information corresponding to solar device-related information (e.g., a corresponding solar device) to the electronic device 101 in response to the solar device characteristic-related information request message. A related embodiment is described below with reference to FIG. 21B.

According to an embodiment, the electronic device 101 may obtain solar power generation effect information based on location-related information, space-related information, window transmission loss rate-related information, and solar device-related information included in at least one simulation-related information. For example, the electronic device 101 may obtain solar power generation effect information using sunlight-related information obtained based on space-related information, window transmission loss rate-related information, location-related information, and solar device characteristic-related information obtained based on solar device-related information. A related embodiment is described below with reference to FIGS. 18 to 20. In operation 5030, based on the result data of the solar power generation simulation, the electronic device 101 may display the recommended placement area and/or solar power generation effect-related information for the solar device on a space or a map associated with the space. For the description of operation 5030, a reference may be made to the description of operation 3050 of FIG. 3. Therefore, no duplicate description is given.

Hereinafter, for convenience of description, under the assumption that the result data of the solar power generation simulation is generated by the server 200, various embodiments (e.g., embodiments of FIGS. 6 to 20) of the disclosure are described, but the disclosure is not limited thereto. For example, as described above with reference to FIG. 5, the result data of the solar power generation simulation may be generated by the electronic device 101. Accordingly, in the following embodiments, the operations performed by the server 200 to generate the result data of the solar power generation simulation may be understood as operations performed by the electronic device 101. For example, in FIGS. 6 to 18, the operations performed by the server 200 may be performed by the electronic device 101.

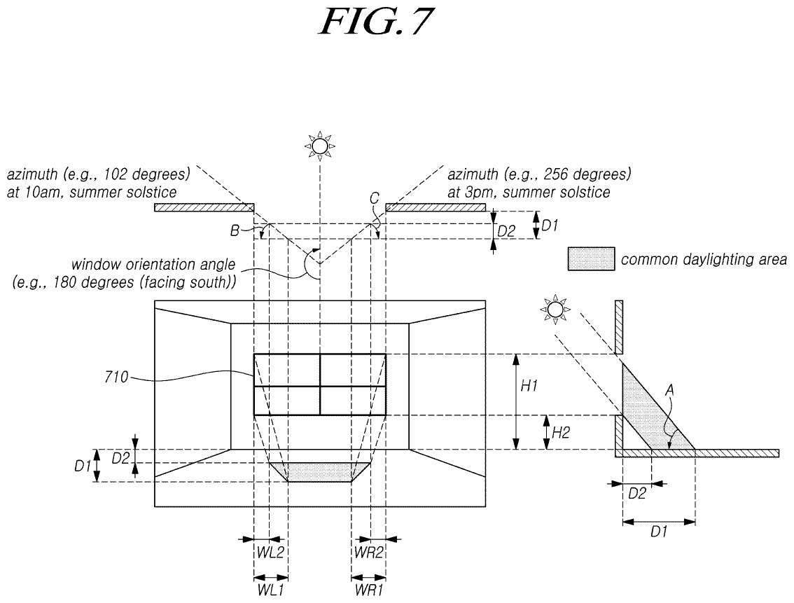

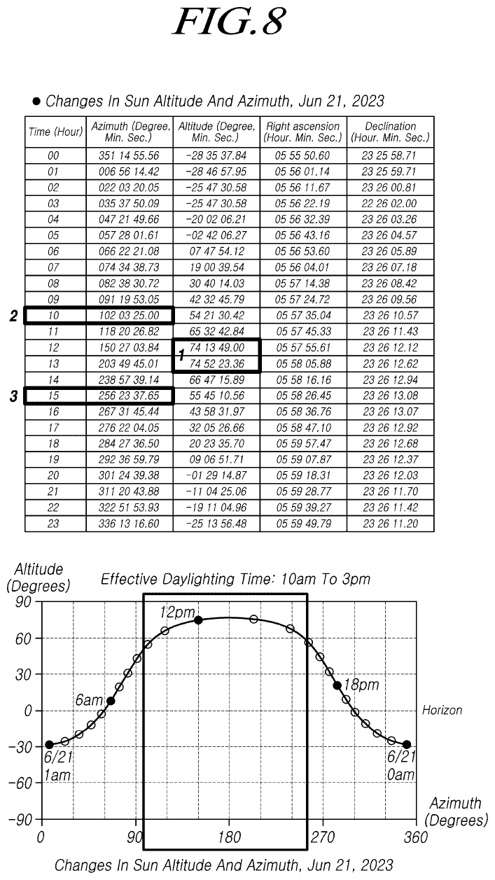

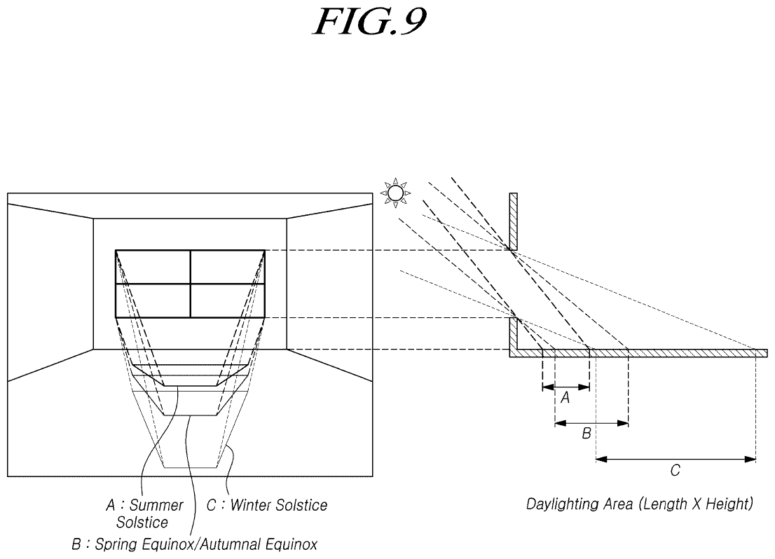

FIG. 6 is a flowchart illustrating an operation for obtaining recommended placement area information according to an embodiment of the disclosure. FIG. 7 is a view illustrating a method for determining a common daylighting area for obtaining recommended placement area information according to an embodiment of the disclosure. FIG. 8 is a view illustrating a method for determining the altitude and azimuth of the sun for determining a common daylighting area according to an embodiment of the disclosure. FIG. 9 is a view illustrating a change in a common daylighting area according to a change in season according to an embodiment of the disclosure.

Referring to FIG. 6, in operation 6010, a server (e.g., the server 200 of FIGS. 2 and 3) may determine a common daylighting area, based on sunlight-related information obtained by the space-related information and the location-related information. The common daylighting area may be, e.g., a common area among areas where sunlight passes through a window in an effective daylighting time (e.g., 10:00 to 3:00) at a designated time point (or date) (e.g., summer solstice, or designated date). For example, the common daylighting area may be an area where is commonly illuminated by sunlight during an effective daylighting time of a designated date.

According to an embodiment, the server 200 may obtain sunlight-related information from an external server (e.g., a weather data server (e.g., the second external server 220 of FIG. 2) based on the location-related information. For example, the server 200 may transmit a sunlight-related information request message including location-related information to the external server, and the external server 220 may transmit a sunlight-related information response message including sunlight-related information corresponding to the corresponding space or place) to the server in response to the sunlight-related information request message. A related embodiment is described below with reference to FIG. 21A.

According to an embodiment, the server 200 may determine the common daylighting area based on the window information included in the space-related information, the information about the altitude of the sun and the information about the azimuth of the sun included in the sunlight-related information. The window information may include, e.g., information about the type, characteristic, location, height, horizontal length and vertical length, size, and/or direction (e.g., the orientation angle of the window) of the corresponding window in the corresponding space.

According to an embodiment, as illustrated in FIG. 7, the common daylighting area may be defined by parameters D1, D2, WL1, WL2, WR1, and WR2. According to an embodiment, the server 200 may calculate the parameters defining the common daylighting area using Equation 1 below.

$$D 1 = H 1 / tan A \qquad [ Equation 1 ]$$

$$D 2 = H 2 / tan A$$

$$WL 1 = D 1 / tan B$$

$$WL 2 = D 2 / tan B$$

$$WR 1 = D 1 / tan C$$

$$WR 2 = D 2 / tan C$$

where,

$$A = Meridian altitude of the sun at the designated time point$$

$$B = {sun}^{′} s azimuth at the start time point of the effective daylighting time at the designated time point + 90 degrees - window orientation angle$$

$$C = {sun}^{′} s azimuth at the end time point of the effective daylighting time at the designated time point + 90 degrees - window orientation angle$$

Hereinafter, as illustrated in FIG. 7, under the assumption that the designated time point is the summer solstice (e.g., Jun. 21, 2023) and the window 710 is facing south (the orientation angle of 180 degrees), a process of calculating parameters defining a common daylighting area is described as an example.

As illustrated in FIG. 8, it may be identified that the effective daylighting time of the summer solstice corresponds to 10:00 to 3:00, and the azimuth angles of the sun at the start time and the end time of the effective daylighting time are about 102 degrees (see part 2 of FIG. 8) and −256 degrees (see part 3 of FIG. 8), respectively. Further, as illustrated in FIG. 8, since the meridian altitude time of the sun at the summer solstice is about 12:30, it may be identified that the meridian altitude of the sun at the summer solstice is about 74.3 degrees, which is an intermediate value between 74.13 degrees (see part 1 of FIG. 8), which is the altitude at 12 o'clock, and 74.52 degrees (see part 1 of FIG. 8), which is the altitude at 13 o'clock.

Accordingly, the parameters A, B, and C may be calculated as follows.

$$A = meridian altitude of the sun at the summer solstice = 74.3 degrees$$

$$B = 10 AM azimuth at the summer solstice + 90 - window orientation angle = 102 + 90 - 180 = 12 degrees$$

$$C = 3 PM azimuth at the summer solstice + 90 + window orientation angle = - 256 + 90 + 180 = 14 degrees$$

Further, the parameters defining the common daylighting area using the parameters A, B, and C may be calculated as follows.

$$D 1 = H 1 / tan A = 1.8 m / tan 74.3 = 0.51 m$$

$$D 2 = H 2 / tan A = 0.5 m / tan 74.3 = 0.14 m ( 14 cm )$$

$$WL 1 = D 1 / tan B = 0.51 m / tan 12 = 2.41 m$$

$$WL 2 = D 2 / tan B = 0.14 m / tan 12 = 0.66 m$$

$$WR 1 = D 1 / tan C = 0.51 m / tan 14 = 2.05 m$$

$$WR 2 = D 2 / tan C = 0.14 m / tan 14 = 0.56 m$$

According to an embodiment, the common daylighting area may be changed according to a seasonal change in the location of the sun. For example, the common daylighting areas during the spring equinox, the autumn equinox, the summer solstice, and the autumn equinox, where a location change of the sun is evident, may be different. For example, as illustrated in FIG. 9, the common daylighting area (area A) at the summer solstice, the common daylighting area (area B) at the spring/autumn equinox, and the common daylighting area (area C) at the winter solstice may be different.

In operation 6020, the server 200 may determine the recommended placement area, based on the common daylighting area.

According to an embodiment, the server 200 may determine the common daylighting are as the recommended placement area.

According to an embodiment, the server 200 may identify whether there is a shadow area in the common daylighting area using surrounding building-related information, and determine the recommended placement area based on the identification result. A related embodiment is described below with reference to FIGS. 10 to 12.

According to an embodiment, the server 200 may determine the recommended placement area in the common daylighting area using the solar device characteristic-related information. Embodiments of the disclosure are described below with reference to FIGS. 13 to 17D.

FIG. 10 is a flowchart illustrating an operation for determining a recommended placement area using surrounding building-related information according to an embodiment of the disclosure. FIG. 11 is a view illustrating a shadow area generated by surrounding buildings according to an embodiment of the disclosure.

The embodiment of FIG. 10 may be an example of operation 6020 of FIG. 6.

In operation 10010, the server (e.g., the server 200 of FIG. 2/3) may obtain surrounding building-related information. For the description of operation 10010, a reference may be made to the description of operation 3030 of FIG. 3. Therefore, no duplicate description is given.

According to an embodiment, the server 200 may obtain surrounding building-related information from an external server (e.g., a building data server (e.g., the third external server 230 of FIG. 2) based on the location-related information. For example, the server 200 may transmit a surrounding building-related information request message including location-related information to the external server, and the external server 230 may transmit a surrounding building-related information response message including surrounding building-related information to the server in response to the surrounding building-related information request message. A related embodiment is described below with reference to FIG. 21A.

According to an embodiment, the surrounding building-related information may include information about the height of at least one building around the building including the corresponding space, the distance to the building, the placement, and/or the shadow. As an example, the surrounding building-related information may include information about the height of each surrounding building located around the corresponding building, the distance to the corresponding building, the placement, and/or the shadow.

In operation 10020, the server 200 may identify whether there is a shadow area in the common daylighting area using surrounding building-related information.

According to an embodiment, the server 200 may determine the shadow area using the location-related information, the sunlight-related information obtained based on the location-related information, and the surrounding building-related information, and identify whether the shadow area is present in the common daylighting area.

According to an embodiment, the server 200 may determine the shadow area based on information about the location and/or height of the first space (e.g., the space corresponding to location 2 of FIG. 11) included in the location-related information, information about the azimuth and/or altitude of the sun included in the sunlight-related information, and information about the height of the surrounding building, size, and/or distance between the building including the first space and the surrounding building included in the surrounding building-related information.

In operation 10030, the server 200 may determine a recommended placement area based on the identification result.

According to an embodiment, when there is no shadow area in the common daylighting area, the server 200 may determine the common daylighting area as the recommended placement area. For example, as shown in part (a) of FIG. 11, in the case of summer (e.g., the summer solstice) when the altitude of the sun is high, the shadow area may not exist in the common daylighting area for the first space (e.g., the space corresponding to location 2) because the shadow area is not generated by the surrounding buildings. In this case, the server 200 may determine the common daylighting area as the recommended placement area.

According to an embodiment, when there is a shadow area in the common daylighting area, the server 200 may identify whether the shadow area is a part of the common daylighting area and determine the recommended placement area based on the identification result. For example, as shown in part (b) of FIG. 11, in the case of winter (e.g., winter solstice) when the altitude of the sun is low, the shadow area 1110 may exist in the common daylighting area for the first space (e.g., the space corresponding to location 2) due to the occurrence of shadow by the surrounding buildings. In this case, the server 200 may determine the recommended placement area based on the identification result.

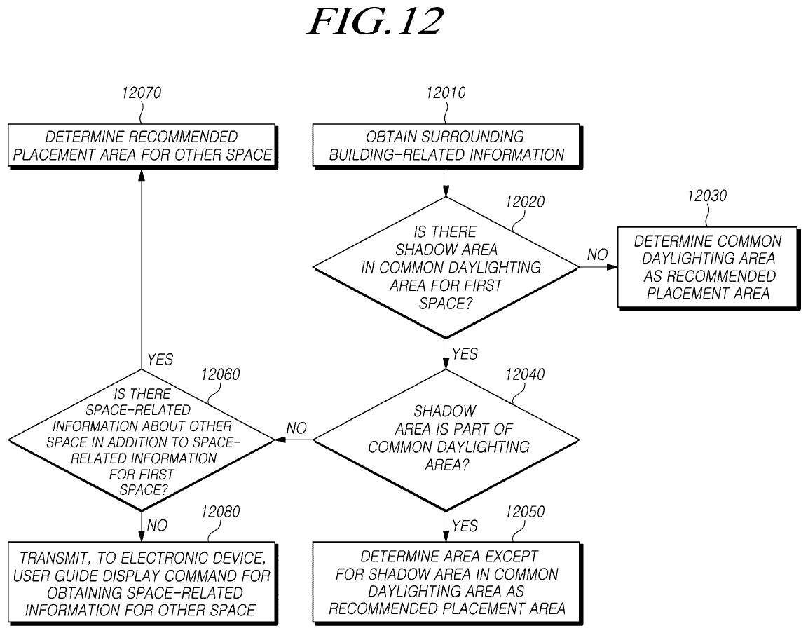

The embodiment of operation 10030 is described below with reference to FIG. 12.

FIG. 12 is a flowchart illustrating an operation for determining a recommended placement area using surrounding building-related information according to an embodiment of the disclosure.

The embodiment of FIG. 12 may be an example of operation 6020 of FIG. 6.

In operation 12010, the server (e.g., the server 200 of FIG. 2/3) may obtain surrounding building-related information. For the description of operation 12010, a reference may be made to the description of operation 10010 of FIG. 10. Therefore, no duplicate description is given.

In operation 12020, the server 200 may identify whether there is a shadow area in the common daylighting area for the first space, using the surrounding building-related information. For the description of operation 12020, a reference may be made to the description of operation 10020 of FIG. 10. Therefore, no duplicate description is given.

In operation 12030, when there is no shadow area in the common daylighting area, the server 200 may determine the common daylighting area as the recommended placement area. For example, as shown in part (a) of FIG. 11, when there is no shadow area in the common daylighting area for the first space (e.g., the space corresponding to location 2) due to the surrounding buildings, the common daylighting area may be determined as the recommended placement area.

In operation 12040, when there is a shadow area in the common daylighting area, the server 200 may identify whether the shadow area is a part of the common daylighting area. For example, as shown in part (b) of FIG. 11, when there is a shadow area in the common daylighting area for the first space (e.g., the space corresponding to location 2) by the surrounding building, it may be identified whether the shadow area is a part of the common daylighting area.

In operation 12050, when the shadow area is a part of the common daylighting area, the server 200 may determine an area other than the shadow area in the common daylighting area as a recommended placement area.

In operation 12060, when the shadow area is not a part of the common daylighting area (e.g., when the shadow area includes the whole common daylighting area), the server 200 may identify whether there is space-related information for another space other than the space-related information for the first space. For example, when the shadow area includes the whole common lighting area of the first space (e.g., a first room), the server 200 may identify whether there is space-related information for the second space (e.g., a living room or a second room) different from the first space. As described above, when a shadow generated by surrounding buildings is present in the whole common daylighting area for the first space, it is difficult to dispose the solar device in the first space, and thus it is necessary to search for another space (the second space) where the solar device is to be placed.

In operation 12070, when the space-related information for the other space exists, the server 200 may determine the recommended placement area for the other space based on the space-related information for the other space. For a description of determining a recommended placement area for the other space, the description made above with reference to FIGS. 6 to 11 may be referred to.

In operation 12080, when there is no space-related information for another space, the server 200 may transmit, to the electronic device 101, a command (a user guide display command) for displaying a user guide for obtaining space-related information for the other space on the electronic device (e.g., the electronic device 101 of FIGS. 1, 2, and 3). In this case, the server 200 may obtain space-related information for the other space through the electronic device 101 and may determine a recommended placement area for the other space based on the space-related information for the other space. For a description of determining a recommended placement area for the other space, the description made above with reference to FIGS. 6 to 11 may be referred to.

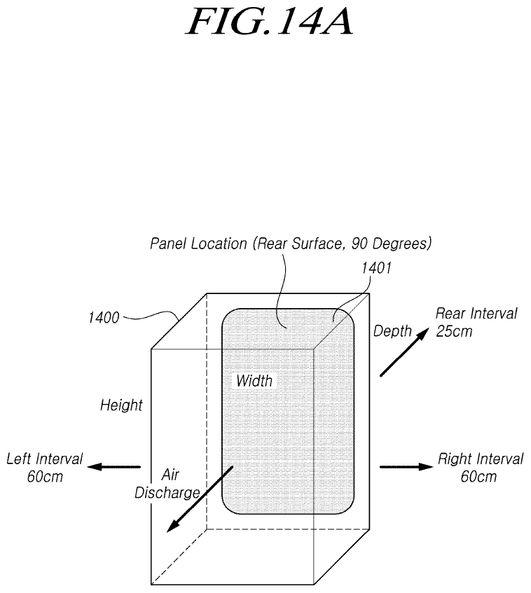

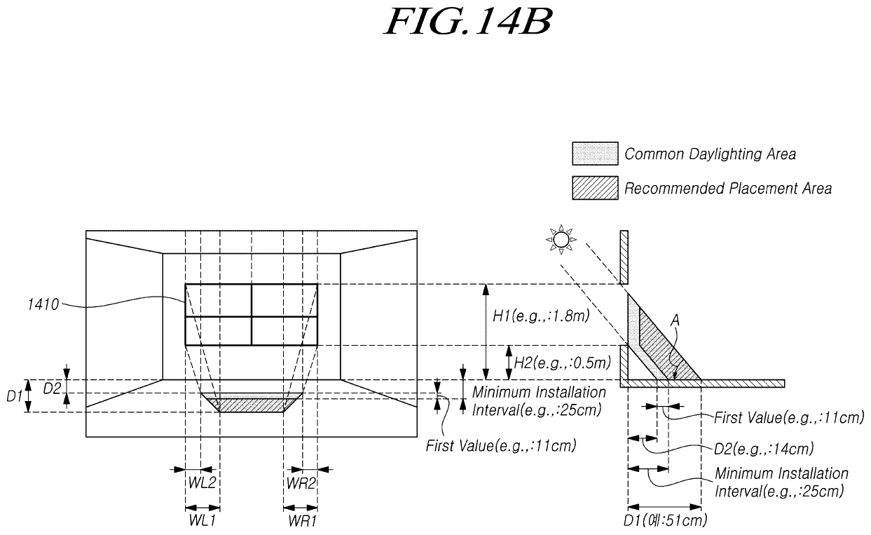

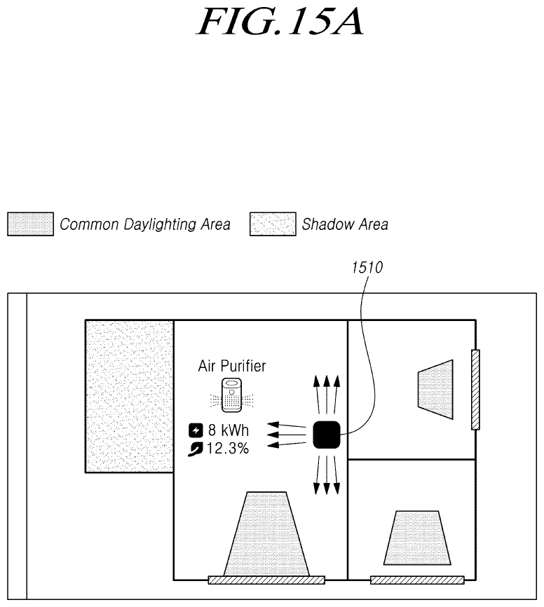

FIG. 13 is a flowchart illustrating an operation for determining a recommended placement area using solar device characteristic-related information according to an embodiment of the disclosure. FIG. 14A is a view illustrating characteristics of a solar device according to an embodiment of the disclosure. FIG. 14B is a view illustrating an example recommended placement area for a solar device having the characteristics of FIG. 14A according to an embodiment of the disclosure.

The embodiment of FIG. 13 may be an example of operation 6020 of FIG. 6.

In operation 13010, the server (e.g., the server 200 of FIG. 2/3) may obtain solar device characteristic-related information. For the description of operation 13010, a reference may be made to the description of operation 3030 of FIG. 3. Therefore, no duplicate description is given.

According to an embodiment, the server 200 may obtain the solar device characteristic-related information from an external server (e.g., a product data server (e.g., the first external server 210 of FIG. 2) based on the solar device-related information. For example, the server 200 may transmit a solar device characteristic-related information request message including solar device characteristic-related information to the external server 210, and the external server 210 may transmit a solar device characteristic-related information response message including solar device characteristic-related information to the server 200 in response to the solar device characteristic-related information request message. A related embodiment is described below with reference to FIG. 21A.

According to an embodiment, the solar device characteristic-related information may include information about the size of the solar device, the number, size, installation location (or placement location) and angle of the solar cell panels included in (or attached to) the solar device, panel angle loss rate, and power consumption, installation interval (or placement interval), and/or operation characteristics (e.g., air flow for an air purifier) of the solar device.

In operation 13020, the recommended placement area in the common daylighting area may be determined using the solar device characteristic-related information.

For example, as illustrated in FIG. 14A, the solar device 1400 may have the characteristics that the solar panel 1401 is placed at an angle of 90 degrees on the rear surface, air is discharged to the front surface (and/or the left/right surface), and the minimum placement intervals required for the air suction space is 25 cm from the rear surface, 60 cm from the left surface, and 60 cm from the right surface. In other words, a rear interval of 25 cm, a left and a right interval of 60 cm respectively are required for disposing the solar device. In this case, as illustrated in FIG. 14B, since a partial area of the common daylighting area does not meet the minimum placement interval (=25 cm) of the rear surface, an area other than the corresponding area in the common daylighting area may be determined as the recommended placement area. For example, as illustrated in FIG. 14B, since D2 (=14 cm), which is the distance from the wall surface (back wall surface) including the window 1410 to the start portion of the common daylighting area, is smaller than the minimum placement interval (=25 cm) of the rear surface by a first value (=11 cm), the server 200 may determine an area other than the area corresponding to the first value in the common daylighting area as the recommended placement area.

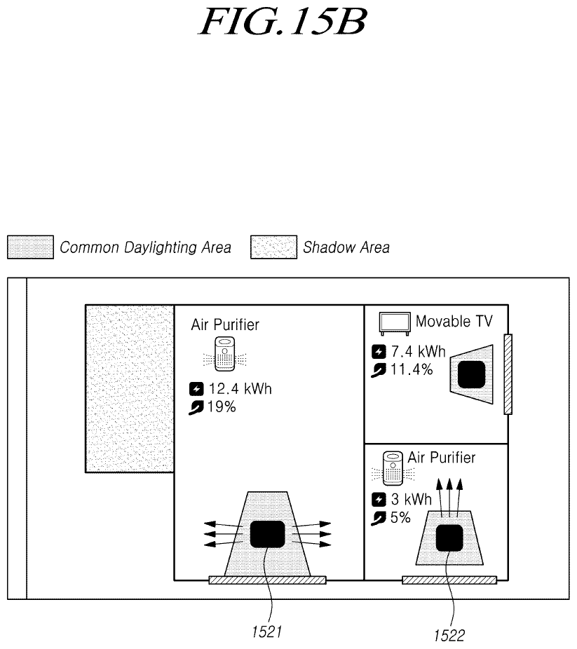

FIG. 15A is a view illustrating an example recommended placement area when one solar device is placed in a plurality of spaces according to an embodiment of the disclosure. FIG. 15B is a view illustrating a recommended placement area when a plurality of solar devices are placed in a plurality of spaces according to an embodiment of the disclosure.

The solar device (e.g., the solar device 10 of FIG. 2) of the embodiments of FIGS. 15A and 15B may be a movable device movable by the user, but is not limited thereto.

According to an embodiment, when one solar device is required to be placed in a plurality of spaces, the server (e.g., the server 200 of FIG. 2/3) may determine which function of the solar power generation function or the device basic function is to be prioritized, and may determine the recommended placement area based on the prioritized function. For example, when only one solar device is selected for solar power generation simulation for a plurality of spaces in the electronic device 101, the server 200 may determine which function of the solar power generation function or the device basic function is to be prioritized, and may determine the recommended placement area based on the prioritized function. In this case, the recommended placement area may not be included in the common daylighting area.

For example, as illustrated in FIG. 15A, only one air purifier may be selected for space 1, space 2, and space 3 for solar power generation simulation. In this case, when the air purifier is placed in one specific common daylighting area (e.g., the common daylighting area of space 1) to increase the solar power generation effect, the air purifying effect for the entire space may not be good. Accordingly, the server 200 may prioritize the air purifying function, which is the device basic function, over the solar power generation function, and determine the recommended placement area 1510 for the air purifier as the center area of the entire space, as illustrated in FIG. 15A. In this case, the server 200 may determine the recommended placement area based on the minimum placement interval (e.g., the minimum placement interval of FIG. 14A) of the air purifier. For the description of determining the recommended placement area in the common daylighting area based on the minimum placement interval, the description of FIGS. 13 to 14B may be referred to.

According to an embodiment, when a plurality of solar devices are required to be placed in a plurality of spaces, the server 200 may determine a recommended placement area for each of the plurality of solar devices considering both the solar power generation function and the device basic function. For example, when a plurality of solar devices are selected for solar power generation simulation for a plurality of spaces in the electronic device 101, the server 200 may determine a recommended placement area for each of the plurality of solar devices considering both the solar power generation function and the device basic function. For example, the server 200 may determine an area where a first area having a high effect of the solar power generation function (e.g., the amount of solar power generation) and a second area having a high effect of the device basic function (e.g., an air purifying effect) overlap each other as a recommended placement area, and the electronic device 101 may display the first area and the second area overlapping each other on the screen.

For example, as illustrated in FIG. 15B, two air purifiers in space 1, space 2, and space 3 may be selected for solar power generation simulation. In this case, the server 200 may determine the recommended placement area of each air purifier by considering both the solar power generation function and the air purifying function. For example, as illustrated in FIG. 15B, the server 200 may determine a first recommended placement area 1521 in the common daylighting area of space 1 based on the minimum placement interval (e.g., the minimum placement interval of FIG. 14A) of the first air purifier, and may determine a second recommended placement area 1522 in the common daylighting area of space 2 based on the minimum placement interval of the second air purifier. For the description of determining the recommended placement area in the common daylighting area based on the minimum placement interval, the description of FIGS. 13 to 14B may be referred to.

Meanwhile, according to an embodiment, the electronic device 101 may display (e.g., duplicate display) an area having a high effect on the basic function (e.g., an area having a high air purifying effect) and an area having a high effect of solar power generation (e.g., an area having a high annual solar power generation) together on the screen.

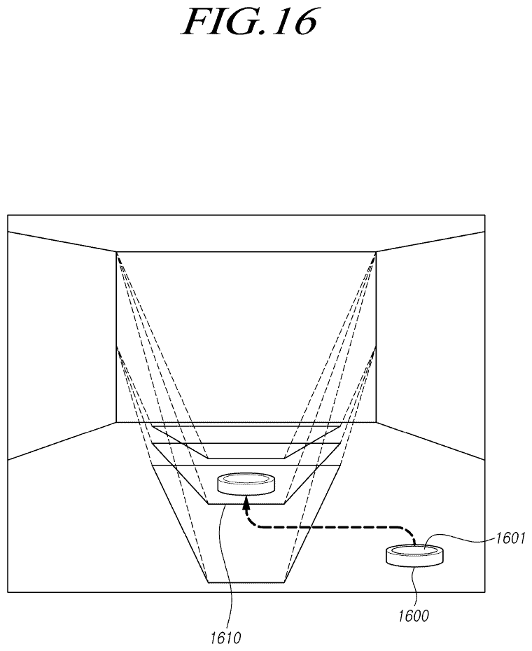

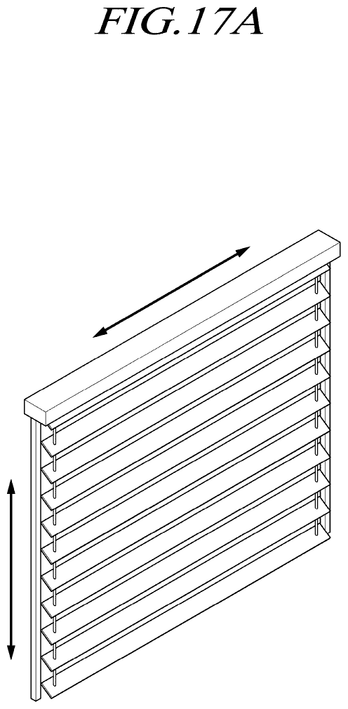

FIG. 16 is a view illustrating a recommended placement area for a self-movable solar device according to an embodiment. In the embodiment of FIG. 16, for convenience of description, it is exemplified that a self-movable solar device 1600 is a robot vacuum cleaner to which the solar panel 1601 is attached to an upper end of the body. However, embodiments are not limited thereto, and various types of electronic devices capable of moving by themselves may be described in the same or similar manner.

According to an embodiment, the server (e.g., the server 200 of FIG. 2/3) may determine the recommended placement area 1610 on the day where the solar device 1600 operates or at a defined period (e.g., a one-day period).

According to an embodiment, the server 200 may transmit information about the determined recommended placement area 1610 to the solar device 1600. As illustrated in FIG. 16, the solar device 1600 may move itself into the recommended placement area 1610 based on the received information about the recommended placement area. The solar device 1600 may perform a solar power generation function in the moved recommended placement area 1610.

According to an embodiment, the server 200 may transmit information about the determined recommended placement area 1610 and information about the location of the solar device 1600 to an electronic device (e.g., the electronic device 101 of FIGS. 1, 2, and 3). The electronic device 101 may display the recommended placement area and the location of the solar device 1610 on the screen.

Meanwhile, according to an embodiment, the solar panel 1601 may not be attached to the upper end of the body of the robot vacuum cleaner 1600, but may be attached to the rear surface of the station of the robot vacuum cleaner 1600. In this case, for the determination of the recommended placement area 1610 for the robot vacuum cleaner 1600 (or station), the description of the embodiments of FIGS. 15A and 15B for the movable device may be referred to.

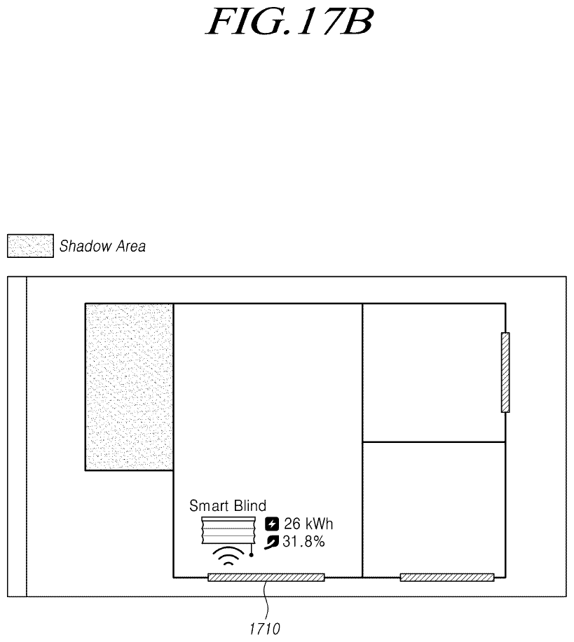

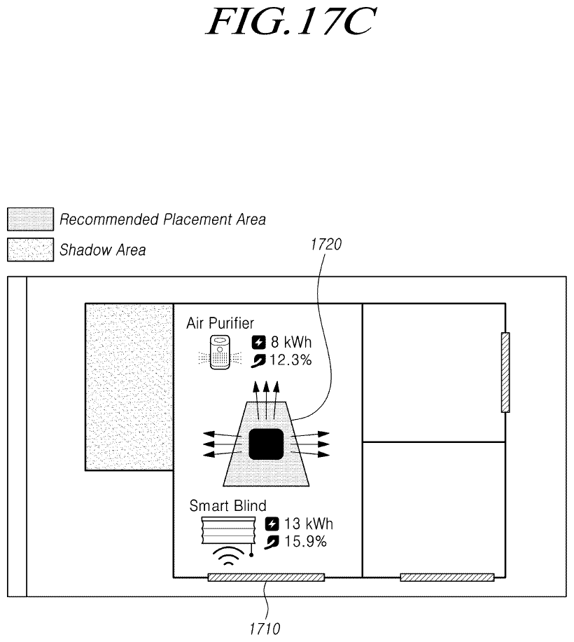

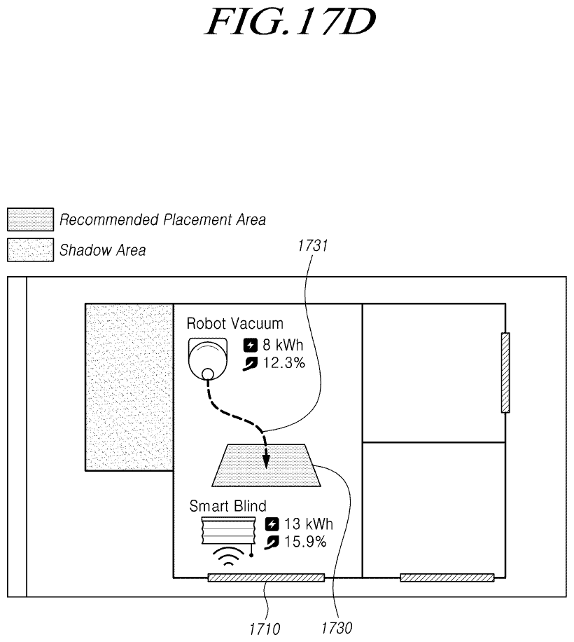

FIG. 17A is a view illustrating an example range-adjustable solar device according to an embodiment of the disclosure. FIG. 17B is a view illustrating an example recommended placement area when a range-adjustable solar device alone is placed according to an embodiment of the disclosure. FIG. 17C is a view illustrating an example recommended placement area when a range-adjustable solar device together with a movable solar device is placed according to an embodiment of the disclosure. FIG. 17D is a view illustrating an example recommended placement area when a range-adjustable solar device together with a self-movable solar device is placed according to an embodiment of the disclosure.

In the embodiments of FIGS. 17A to 17D, for convenience of description, it is exemplified that a range-adjustable solar device is a smart blind to which a solar panel is attached. However, embodiments are not limited thereto, and various types of electronic devices capable of range adjustment may be described in the same or similar manner.

According to an embodiment, the electronic device 101 may change the weight of solar power generation of the smart blind according to whether the smart blind is installed alone or together with another solar device 10, and may display solar power generation effect information of the smart blind according to the weight on the screen.

Referring to FIG. 17A, the location of the smart blind is not changed because the smart blind is placed on the window, but the range may be changed up and down or left and right.

According to an embodiment, the smart blind may be placed on or adjacent to a window.

According to an embodiment, the size of the smart blind may be defined (or set) based on the size of the window included in the window information.

According to an embodiment, the smart blind may include at least one slat to which a solar panel is attached, and may perform solar power generation by automatically adjusting the slope of the slat according to the location (e.g., altitude and/or azimuth) of sunlight.

According to an embodiment, when the entire smart blind is lowered to cover the entire window, the smart blind may perform maximum solar power generation. When a portion of the smart blind is lowered to cover only a portion of the window, the solar device (e.g., a movable device or a self-movable device) other than (or in addition to) the smart blind may perform solar power generation using sunlight transmitted through the corresponding window.

Referring to FIG. 17B, the smart blind may be placed alone in the space.

According to an embodiment, when one smart blind is required to be placed in the space, the server (e.g., the server 200 of FIG. 2/3) may determine an area corresponding to the window as the recommended placement area 1710. For example, when only one smart blind for the space is selected by an electronic device (e.g., the electronic device 101 of FIG. 1/2) for solar power generation simulation, the server 200 may determine the area corresponding to the window (e.g., an area having the same size as the window) as a recommended placement area. In this case, as illustrated in FIG. 17B, the electronic device 101 may display the recommended placement area for the smart blind and solar power generation effect-related information in the recommended placement area on the screen. The solar power generation effect-related information may include, e.g., information about the amount of power generation and the energy saving rate when the maximum solar power generation is performed by lowering the entire smart blind in the recommended placement area, but is not limited thereto. For example, according to an embodiment, the solar power generation effect-related information may include information about the amount of power generation and the energy saving rate when solar power generation is performed by lowering only a portion (e.g., half) of the smart blind in the recommended placement area.

Referring to FIG. 17C, the smart blind may be placed together with a movable solar device (e.g., an air purifier) in the space. In the example of FIG. 17C, for convenience of description, an example where the movable solar device is an air purifier is described, but embodiments are not limited thereto. For example, the same or similar description may also apply to various types of electronic devices movable by the user.

According to an embodiment, when the smart blind and the air purifier are required to be placed together in the space, the server 200 may recognize that the smart blind and the air purifier are placed together in the space. For example, when the smart blind and the air purifier are selected together for the solar power generation simulation for the space by the electronic device 101, or when the smart blind and the air purifier are sequentially selected for the solar power generation simulation, the server 200 may recognize that the smart blind and the air purifier are placed together in the space.

According to an embodiment, when the smart blind and the air purifier are placed together in the space, the server 200 may determine an area corresponding to the window (e.g., an area having the same size as the window) as the recommended placement area 1710 for the smart blind, and may determine an area other than the area corresponding to the minimum placement interval (e.g., the minimum placement interval of FIG. 14A) in the common daylighting area as the recommended placement area 1720 for the air purifier. For the description of the recommended placement area for the air purifier, the description of FIGS. 14A and 14B may be referred to.

According to an embodiment, as illustrated in FIG. 17C, the electronic device 101 may display the recommended placement area and solar power generation effect-related information in the recommended placement area for the smart blind on the screen. The solar power generation effect-related information for the smart blind may include, e.g., information about the amount of power generation and the energy saving rate when solar power generation is performed by lowering a portion (e.g., 50%) of the smart blind in the recommended placement area.

Referring to FIG. 17D, the smart blind may be placed together with a self-movable solar device (e.g., a robot vacuum cleaner) in the space. In the example of FIG. 17D, for convenience of description, an example where a self-movable solar device is a robot vacuum cleaner is described, but embodiments are not limited thereto. For example, various types of electronic devices capable of moving by themselves may be described in the same or similar manner.

According to an embodiment, when the smart blind and the robot vacuum cleaner are required to be placed together in the space, the server 200 may recognize that the smart blind and the robot vacuum cleaner are placed together in the space. For example, when the smart blind and the robot vacuum cleaner are selected together for the solar power generation simulation for the space by the electronic device 101, or when the smart blind and the robot vacuum cleaner are sequentially selected for the solar power generation simulation, the server 200 may recognize that the smart blind and the robot vacuum cleaner are placed together in the space.

According to an embodiment, when the smart blind and the robot vacuum cleaner are placed together in the space, the server 200 may determine an area corresponding to the window as the recommended placement area 1710 for the smart blind, and may determine a common daylighting area of the corresponding date as the recommended placement area 1730 for the robot vacuum cleaner. For the description of the recommended placement area for the robot vacuum cleaner, the description of FIG. 16 may be referred to.

According to an embodiment, as illustrated in FIG. 17D, the electronic device 101 may display the recommended placement area and solar power generation effect-related information in the recommended placement area for the smart blind on the screen. The solar power generation effect-related information for the smart blind may include, e.g., information about the amount of power generation and the energy saving rate when solar power generation is performed by lowering a portion (e.g., 50%) of the smart blind in the recommended placement area.

According to an embodiment, as illustrated in FIG. 17D, the electronic device 101 may display the recommended placement area and solar power generation effect-related information in the recommended placement area for the robot vacuum cleaner on the screen. The electronic device 101 may display information 1731 (e.g., an arrow) indicating that the robot vacuum cleaner is movable to the recommended placement area together with the recommended placement area.

FIG. 18 is a flowchart illustrating an operation for obtaining solar power generation effect information according to an embodiment of the disclosure.

Referring to FIG. 18, in operation 18010, a server (e.g., the server 200 of FIG. 2/3) may calculate a module solar irradiation (e.g., an annual module solar irradiation).

According to an embodiment, the server 200 may calculate the annual module solar irradiation using sunlight-related information obtained based on space-related information, window transmission loss rate-related information, and location-related information, and solar device characteristic-related information obtained based on solar device-related information. For example, the server 200 may calculate the annual module solar irradiation using Equation 2 below.

$$Annual module solar irradiation ( kWh / year ) = annual solar irradiation ( kWh / {m}^{2} ) * window transmission loss rate * module angle loss rate * panel size ( {m}^{2} ) * number of panels \qquad [ Equation 2 ]$$

According to an embodiment, the annual solar irradiation may be obtained based on the solar irradiation information included in the sunlight-related information. The window transmission loss rate may be obtained based on transmission loss rate information or illuminance information included in the window transmission loss rate-related information. The module angle loss rate, the panel size, and the number of panels may be respectively obtained based on information about the module angle loss rate, the size of the solar panel, and the number of solar panels included in the solar device characteristic-related information.

For example, when the annual solar irradiation is 1204.167 kWh/m², the window transmission loss rate is 0.645, the module angle loss rate is 0.62, the panel size is 0.02225 m², and the number of panels is 6, the annual module solar irradiation is 1204.167 kWh/m²*0.645*0.62*0.02225 m²*6=65.025 kWh/year.

In operation 18020, the server 200 may calculate the amount of solar power generation (e.g., the annual solar power generation) based on the module solar irradiation (e.g., the annual module solar irradiation).

According to an embodiment, the server 200 may calculate the annual solar power generation using the annual module solar irradiation and the solar device characteristic-related information (e.g., panel power generation efficiency) obtained based on the solar device-related information. For example, the server 200 may calculate the annual solar power generation using Equation 3 below.

$$Annual solar power generation ( kWh / year ) = annual module solar irradiation ( kWh / year ) * panel power generation efficiency \qquad [ Equation 3 ]$$

According to an embodiment, the panel power generation efficiency may be obtained based on information about the power generation efficiency of the solar panel included in the solar device characteristic-related information.

For example, when the annual module solar irradiation is 65.025 kWh/year and the panel power generation efficiency is 15%, the annual solar power generation amount is 65.025 kWh/m²*0.15=9.753 kWh/year.

In operation 18030, the server 200 may calculate the energy saving rate (e.g., the annual energy saving rate) based on the amount of solar power generation (e.g., the annual solar power generation).

According to an embodiment, the server 200 may calculate the annual solar power generation using the annual solar power generation and the solar device characteristic-related information (e.g., annual power consumption) obtained based on the solar device-related information. For example, the server 200 may calculate the annual energy saving rate using Equation 4 below.

$$Annual energy saving rate ( \% ) = annual solar power generation ( kWh / year ) \div annual power consumption * 100 \qquad [ Equation 4 ]$$

According to an embodiment, the annual power consumption may be obtained based on information about power consumption (e.g., annual power consumption) included in the solar device characteristic-related information.

For example, when the annual solar power generation is 9.753 kWh/year and the annual power consumption is 64.8 kWh, the annual energy saving rate is 9.753 kWh/year÷64.8 kWh*100=15%.

FIG. 19 is a flowchart illustrating an operation for calculating a window transmission loss rate according to an embodiment of the disclosure. FIG. 20 illustrates an example screen provided for an electronic device to calculate an illuminance value for calculating a window transmission loss rate according to an embodiment of the disclosure.

Referring to FIG. 19, in operation 19010, the electronic device (e.g., the electronic device 101 of FIG. 1/2) may obtain a first illuminance value measured through the illuminance sensor while the window is open.

According to an embodiment, to measure the first illuminance value, the electronic device 101 may display a first user interface as shown in part (a) of FIG. 20 on the screen. Referring to part (a) of FIG. 20, the first user interface may include a user guide, such as “Open the window, hold the phone vertically, and measure illuminance” and/or a measurement button. The electronic device may measure the first illuminance value through the illuminance sensor in response to receiving a user input for selecting the measurement button.

In operation 19020, the electronic device 101 may obtain a second illuminance value measured through the illuminance sensor while the window is closed. According to an embodiment, operation 19020 may be performed before operation 19010.

According to an embodiment, the electronic device 101 may display a second user interface as shown in part (b) of FIG. 20 on the screen to measure the second illuminance value. Referring to part (b) of FIG. 20, the second user interface may include a user guide such as “close the window, hold the phone vertically, and measure illuminance” and/or a measurement button. The electronic device may measure the second illuminance value through the illuminance sensor in response to receiving a user input for selecting the measurement button.

In operation 19030, the electronic device 101 may calculate the window transmission loss rate using the first illuminance value and the second illuminance value. Here, the window transmission loss rate may be a loss rate generated when sunlight passes through the window. For example, when the first illuminance value is 100 Lux and the second illuminance value is 64.5 Lux, the window transmission loss rate corresponds to 0.645 (or 64.5%).

Meanwhile, operation 19030 may be performed by a server (e.g., the server 200 of FIG. 2/3), rather than the electronic device 101. In this case, the electronic device 101 may transmit illuminance information including the first illuminance value and the second illuminance value to the server 200 without performing an operation of calculating the window transmission loss rate, and the server 200 may calculate the window transmission loss rate using the first illuminance value and the second illuminance value.

FIG. 21A is a flowchart illustrating a solar power generation simulation procedure according to an embodiment of the disclosure.

For the description of the embodiment of FIG. 21A, the description of the embodiments of FIGS. 3 to 20 may be referred to. No duplicate description thereof is presented below.

In the solar power generation simulation procedure of FIG. 21A, result data of the solar power generation simulation may be generated by the server 200.

Referring to FIG. 21A, in operation 21010a, the electronic device 101 may obtain location-related information. In operation 21011a, the electronic device 101 may transmit location-related information to the server 200. For the description of the location-related information, the description of FIG. 3 may be referred to.

In operation 21020a, the server 200 may transmit a sunlight-related information request message to the second external server 220 (e.g., a weather data server) based on the received location-related information. For example, the server 200 may transmit a sunlight-related information request message including location-related information to the second external server 220.

In operation 21021a, the second external server 220 may transmit a sunlight-related information response message to the server 200 in response to the sunlight-related information request message. For example, the second external server 220 may transmit a sunlight-related information response message including sunlight-related information to the server 200 in response to the sunlight-related information request message. For the description of the sunlight-related information, the description of FIGS. 3, 6 to 9 may be referred to.

In operation 21030a, the server 200 may transmit a surrounding building-related information request message to the third external server 230 (e.g., a building data server) based on the received location-related information. For example, the server 200 may transmit a surrounding building-related information request message including location-related information to the third external server 230.

In operation 21031a, the third external server 230 may transmit a surrounding building-related information response message to the server 200 in response to the surrounding building-related request message. For example, the third external server 230 may transmit a surrounding building-related response message including the surrounding building-related information to the server 200 in response to the surrounding building-related request message. For the description of the surrounding building-related information, the description of FIG. 3 may be referred to.

In operation 21040a, the electronic device 101 may obtain space-related information. In operation 21041a, the electronic device 101 may transmit space-related information to the server 200. For the description of the space-related information, the description of FIGS. 3, 10, and 11 may be referred to.

In operation 21050a, the electronic device 101 may obtain solar device-related information. In operation 21051a, the electronic device 101 may transmit solar device-related information to the server 200. For the description of the solar device-related information, the description of FIG. 3 may be referred to.

In operation 21060a, the server 200 may transmit a solar device characteristic-related information request message to the first external server 210 (e.g., a product data server) based on the received solar device-related information. For example, the server 200 may transmit a solar device characteristic-related information request message including solar device-related information to the first external server 210.

In operation 21061a, the first external server 210 may transmit the solar device characteristic response message to the server 200 in response to the solar device characteristic-related information request message. For example, in response to the solar device characteristic-related information request message, the first external server 210 may transmit the solar device characteristic-related information response message including the solar device characteristic-related information to the server 200. For the description of the solar device characteristic-related information, the description of FIGS. 3, 13 to 17D may be referred to.

In operation 21070a, the electronic device 101 may obtain window transmission loss rate-related information. In operation 21071a, the electronic device 101 may transmit window transmission loss rate-related information to the server 200. For the description of the window transmission loss rate information, the description of FIGS. 3, 19, and 20 may be referred to.

In operation 21080a, the server 200 may obtain recommended placement area information and solar power generation effect information. For the description of obtaining the recommended placement area information, the description of FIGS. 3, 5, and 6 to 17D may be referred to. For the description of the solar power generation effect information, the description of FIGS. 3, 5, and 18 may be referred to.

In operation 21081a, the server 200 may transmit recommended placement area information and solar power generation effect information to the electronic device 101.

In operation 21090a, the electronic device 101 may display information related to the recommended placement area and the solar power generation effect based on the recommended placement area information and the solar power generation effect information. For the description of display of the recommended placement area and the solar power generation effect-related information, the description of FIGS. 3, 4, 15A and 15B, and 17B to 17D may be referred to.

Meanwhile, the above-described operations may be performed in a different order from the illustrated order, or a plurality of operations may be performed in parallel with each other. For example, operations 21010a/21011a, operations 21040a/21041a, operations 21050a/21051a, and/or operations 21070a/21071a may be performed in parallel with each other. For example, operations 21020a/20021a, operations 21030a/21031a, and/or operations 21060a/21061a may be performed after operation 21071a is performed, or may be performed at a time point when information to be obtained through the corresponding operation is required. Further, some of the above-described operations may be omitted, or additional operations may be further performed.

FIG. 21B is a flowchart illustrating a solar power generation simulation procedure according to an embodiment of the disclosure.

For the description of the embodiment of FIG. 21B, the description of the embodiments of FIGS. 3 to 20 may be referred to. No duplicate description thereof is presented below.

In the solar power generation simulation procedure of FIG. 21B, unlike the solar power generation simulation procedure of FIG. 21A, result data of the solar power generation simulation may be generated by the electronic device 101.

Referring to FIG. 21B, in operation 21010b, the electronic device 101 may obtain location-related information. For the description of the location-related information, the description of FIG. 3 may be referred to.

In operation 21020b, the electronic device 101 may transmit a sunlight-related information request message to the second external server 220 (e.g., a weather data server) based on the received location-related information. For example, the electronic device 101 may transmit a sunlight-related information request message including location-related information to the second external server 220.

In operation 21021b, the second external server 220 may transmit a sunlight-related information response message to the electronic device 101 in response to the sunlight-related information request message. For example, the second external server 220 may transmit a sunlight-related information response message including sunlight-related information to the electronic device 101 in response to the sunlight-related information request message. For the description of the sunlight-related information, the description of FIGS. 3, 6 to 9 may be referred to.

In operation 21030b, the electronic device 101 may transmit a surrounding building-related information request message to the third external server 230 (e.g., a building data server) based on the received location-related information. For example, the electronic device 101 may transmit a surrounding building-related information request message including location-related information to the third external server 230.

In operation 21031b, the third external server 230 may transmit a surrounding building-related information response message to the electronic device 101 in response to the surrounding building-related request message. For example, the third external server 230 may transmit a surrounding building-related response message including the surrounding building-related information to the electronic device 101 in response to the surrounding building-related request message. For the description of the surrounding building-related information, the description of FIG. 3 may be referred to.

In operation 21040b, the electronic device 101 may obtain space-related information. For the description of the space-related information, the description of FIGS. 3, 10, and 11 may be referred to.

In operation 21050b, the electronic device 101 may obtain solar device-related information. For the description of the solar device-related information, the description of FIG. 3 may be referred to.

In operation 21060b, the electronic device 101 may transmit a solar device characteristic-related information request message to the first external server 210 (e.g., a product data server) based on the received solar device-related information. For example, the electronic device 101 may transmit a solar device characteristic-related information request message including solar device-related information to the first external server 210.

In operation 21061b, the first external server 210 may transmit the solar device characteristic response message to the electronic device 101 in response to the solar device characteristic-related information request message. For example, in response to the solar device characteristic-related information request message, the first external server 210 may transmit the solar device characteristic-related information response message including the solar device characteristic-related information to the electronic device 101. For the description of the solar device characteristic-related information, the description of FIGS. 3, 13 to 17D may be referred to.

In operation 21070b, the electronic device 101 may obtain window transmission loss rate-related information. For the description of the window transmission loss rate information, the description of FIGS. 3, 19, and 20 may be referred to.

In operation 21080b, the electronic device 101 may obtain recommended placement area information and solar power generation effect information. For the description of obtaining the recommended placement area information, the description of FIGS. 3, 5, and 6 to 17D may be referred to. For the description of the solar power generation effect information, the description of FIGS. 3, 5, and 18 may be referred to. As described above, in each embodiment for obtaining the recommended placement area information and solar power generation effect information, the operations performed by the server 200 may be understood as operations performed by the electronic device 101.

In operation 21090b, the electronic device 101 may display information related to the recommended placement area and the solar power generation effect based on the recommended placement area information and the solar power generation effect information. For the description of display of the recommended placement area and the solar power generation effect-related information, the description of FIGS. 3, 4, 15A and 15B, and 17B to 17D may be referred to.

Meanwhile, the above-described operations may be performed in a different order from the illustrated order, or a plurality of operations may be performed in parallel with each other. For example, operation 21010b, operation 21040b, operation 21050b, and/or operation 21070b may be performed together in parallel with each other. For example, operation 21020b, operation 21030b, and/or operation 21060b may be performed after operation 21071b is performed, or may be performed at a time point when information to be obtained through the corresponding operation is required. Further, some of the above-described operations may be omitted, or additional operations may be further performed.

FIGS. 22A to 22E illustrate example screens provided for an electronic device to obtain information for a solar power generation simulation according to an embodiment of the disclosure.

Referring to FIGS. 22A to 22E, an electronic device (e.g., the electronic device 101 of FIG. 1/2) may provide a screen including an associated user interface step by step to obtain at least one information (simulation-related information) for solar power generation simulation for a solar device. For the description of the at least one simulation-related information, the description of FIG. 3 may be referred to.

As illustrated in FIG. 22A, the electronic device 101 may display a screen 22010 including a first user interface for requesting to input an address of a space (or a place including a space) where the solar device is to be placed. The electronic device 101 may obtain address information (or location-related information including address information) of the space, based on a user input to at least one address input item in the first user interface. Meanwhile, according to an embodiment, the electronic device 101 may automatically obtain information about the location and/or address of the user (or the electronic device 101) using a sensor of the electronic device 101 such as GPS.

As illustrated in FIG. 22B, the electronic device 101 may display a screen 22020 including a second user interface for requesting 3D scanning for the space (or the place including the space) where the solar device is to be placed. According to an embodiment, the second user interface may include a scanning button for initiating 3D scanning. The electronic device 101 may obtain 3D space information (or space-related information including 3D space information) about the space, based on the 3D scanning data obtained through 3D scanning through the second user interface.

As illustrated in FIG. 22C, the electronic device 101 may display a screen 22030 including a third user interface for requesting selection of a solar device to be placed in the space. The electronic device 101 may obtain solar device-related information for the selected solar device based on a user input for selection of the solar device through the third user interface.

As illustrated in FIG. 22D, the electronic device 101 may display a screen 22040 including a fourth user interface for requesting measurement of a first illuminance value (an illuminance value in a state where a window is open) for calculating a window transmission loss rate. The electronic device 101 may obtain information about the first illuminance value (or window transmission loss rate-related information) based on a user input for measuring the first illuminance value through the fourth user interface. For the description of the fourth user interface, the description of part (a) of FIG. 20 may be referred to.

As illustrated in FIG. 22E, the electronic device 101 may display a screen 22050 including a fifth user interface for requesting measurement of a second illuminance value (an illuminance value in a state where a window is closed) for calculating a window transmission loss rate. The electronic device 101 may obtain information about the second illuminance value (or window transmission loss rate-related information) based on a user input for measuring the second illuminance value through the fifth user interface. For the description of the fifth user interface, the description of part (b) of FIG. 20 may be referred to.

According to an embodiment, the electronic device 101 may obtain at least one information for simulation of solar power generation by sequentially providing the screens (or user interfaces) of FIGS. 22A to 22E. Meanwhile, according to an embodiment, the screens may be provided in a different order from that of FIGS. 22A to 22E.

FIGS. 23A to 23C illustrate example screens provided for an electronic device to show a result of solar power generation simulation according to an embodiment of the disclosure.

Referring to FIGS. 23A to 23C, an electronic device (e.g., the electronic device 101 of FIG. 1/2) may provide at least one screen for showing the result of the solar power generation simulation for the solar device. For example, the electronic device 101 may provide a screen including recommended placement area and/or solar power generation effect-related information, based on the recommended placement area information and/or solar power generation effect information. For the description of the recommended placement area information and the solar power generation effect information, the description of FIGS. 3 to 21B may be referred to.

As illustrated in FIG. 23A, the electronic device 101 may display the recommended placement area obtained using the recommended placement area information and the first information related to the solar power generation effect obtained using the solar power generation effect information. For example, the electronic device 101 may display an augmented image 2301a and 2302a including the recommended placement area obtained using the recommended placement area information and the first information related to the solar power generation effect obtained using the solar power generation effect information in a real space (or a real environment including the corresponding space). For example, the electronic device 101 may display the augmented image 2301a and 2302a including the recommended placement area obtained using the recommended placement area information and the first information related to the solar power generation effect obtained using the solar power generation effect information on an image related to the corresponding space. The image associated with the space may be, e.g., an image (e.g., a 3D image) of the corresponding space generated based on the space-related information (e.g., 3D space information) or an image of the corresponding space captured in real time by the electronic device.

According to an embodiment, the electronic device 101 may display the recommended placement area and the first information related to the solar power generation effect together with the icon and the product name of the solar device.

According to an embodiment, the electronic device 101 may further display a first view mode switching icon 2310a on the screen. The first view mode switching icon 2310a may be an icon for mode switching from the view of FIG. 23A (hereinafter, AR view) to the view in FIG. 23B (hereinafter, Map view). In response to identifying a user input for selecting the first view mode switching icon 2310a while the AR view of FIG. 23A is displayed, the electronic device 101 may switch the AR view to the Map view.

As illustrated in FIG. 23B, the electronic device 101 may display the recommended placement area obtained using the recommended placement area information and the first information related to the solar power generation effect obtained using the solar power generation effect information, on the map associated with the space. According to an embodiment, the map associated with the space may be a map of the place (e.g., the house) including the corresponding space (e.g., the living room) generated based on the space-related information (e.g., 3D space information). The map may further include space(s) in addition to the corresponding space. For example, as illustrated, the map may further include a space 2302b (e.g., a first room) where the air conditioner is placed and a space 2303b (e.g., a second room) where the mobile TV is placed, in addition to the space 2301b (e.g., the living room) where the air purifier is placed. The first information related to the solar power generation effect may include, e.g., information indicating the amount of solar power generation (e.g., annual solar power generation) and/or information indicating the energy saving rate (e.g., annual energy saving rate). In the disclosure, the first information related to the solar power generation effect may be referred to as basic information related to the solar power generation effect. For example, the first information related to the solar power generation effect for the air purifier may include information indicating the annual solar power generation (e.g., 16.67 kWh) for the air purifier and information indicating the annual energy saving rate (e.g., 15% saving).

According to an embodiment, the electronic device 101 may display the recommended placement area and the first information related to the solar power generation effect together with the icon and the product name of the solar device. For example, the electronic device 101 may display the recommended placement area and the first information related to the solar power generation effect together with the icon and the product name of the air purifier.

According to an embodiment, on the map, the electronic device 101 may display a space where the solar device may not be placed, in addition to the space where the recommended placement area is displayed (i.e., the space where the solar device may be placed). For example, the electronic device 101 may display the space where the solar device may not be placed, in a color different from the color of the recommended placement area.

According to an embodiment, the electronic device 101 may further display a second view mode switching icon 2310b on the screen. The second view mode switching icon 2310b may be an icon for mode switch from the Map view of FIG. 23B to the AR view of FIG. 23A. In response to identifying a user input for selecting the second view mode switching icon while the map view of FIG. 23B is displayed, the electronic device 101 may switch the map view to the AR view.

As shown in FIG. 23C, the electronic device 101 may display, on the space, the second information related to the solar power generation effect in response to identifying an event for displaying detailed information about the solar power generation effect in a state in which the first information related to the solar power generation effect is displayed on the space or the map (e.g., the state in which the AR view of FIG. 23A is displayed or the state in which the Map view of FIG. 23B is displayed). For example, the electronic device 101 may display an augmented image including the second information related to the solar power generation effect obtained using the solar power generation effect information on a real space (or a real environment including the corresponding space). For example, the electronic device 101 may display an augmented image including the second information related to the solar power generation effect obtained using the solar power generation effect information on the image related to the corresponding space. The image associated with the space may be, e.g., an image (e.g., a 3D image) of the corresponding space generated based on the space-related information (e.g., 3D space information) or an image of the corresponding space captured in real time by the electronic device 101. According to an embodiment, the real environment (or the image associated with the space) associated with the space where the second information related to the solar power generation effect is displayed may be different from the real environment (or the image associated with the space) associated with the space where the first information related to the solar power generation effect is displayed.

According to an embodiment, the second information related to the solar power generation effect may include information different from the first information related to the solar power generation effect. For example, the second information related to the solar power generation effect may include more information than the first information related to the solar power generation effect. For example, as illustrated in FIG. 23C, the second information related to the solar power generation effect may include information indicating the annual solar power generation (e.g., 16.67 kWh), information indicating the tree effect (e.g., 1.9 tree saving) according to the annual solar power generation (e.g., 16.67 kWh), information indicating the carbon reduction amount (e.g., 7.6 kg Co2 saving) according to the annual solar power generation (e.g., 16.67 kWh), and information indicating the cost saving (e.g., $2.31 saving) according to the annual solar power generation (e.g., 16.67 kWh).

According to an embodiment, the event for displaying the detailed information about the solar power generation effect may include an event where a user input for selecting a specific space displayed on the screen, an icon of the solar device associated with the specific space, or a recommended placement area associated with the specific space is identified.

According to an embodiment, the electronic device 101 may display the recommended placement area and the second information related to the solar power generation effect together with the icon of the solar device, the product name, and the device characteristic display (e.g., display of the air direction of the air purifier as illustrated in FIG. 23C). For example, the electronic device 101 may display the recommended placement area and the second information related to the solar power generation effect together with the icon, the product name, and air direction display of the air purifier. As such, the electronic device 101 may synthesize the attribute of the solar device 10 together with the result of solar power generation simulation into graphics and display it together on the screen.

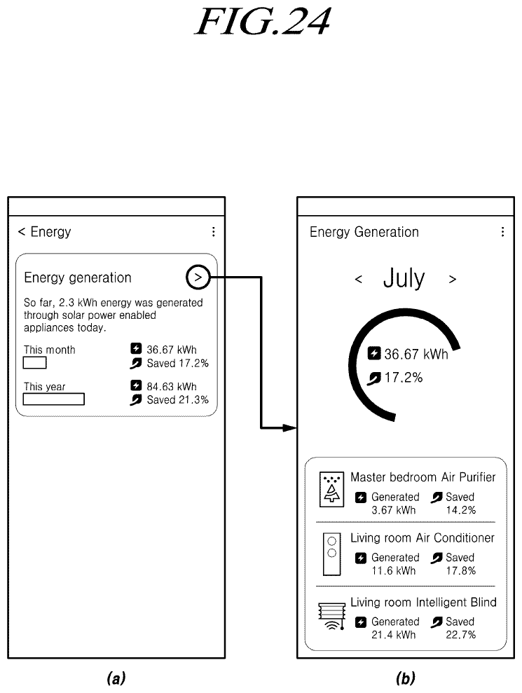

FIG. 24 illustrates an example screen for monitoring a solar power generation effect according to an embodiment of the disclosure.

According to an embodiment, the electronic device (e.g., the electronic device 101 of FIG. 1/2) may display at least one screen (hereinafter, referred to as a “monitoring screen”) for monitoring the solar power generation effect.

According to an embodiment, the monitoring screen may provide information about the energy saving rate, together with or separately from the information about the amount of solar power generation. For the description of the information about the amount of solar power generation and the information about the energy saving rate, the description of FIGS. 2 and 3 may be referred to.

According to an embodiment, the amount of solar power generation provided through the monitoring screen may be expressed as the amount of power generation for each period (e.g., daily, weekly, monthly, yearly, etc.), or may be expressed as the total (lifetime) amount of power generation from the placement (or installation) to the lookup date (the corresponding date).

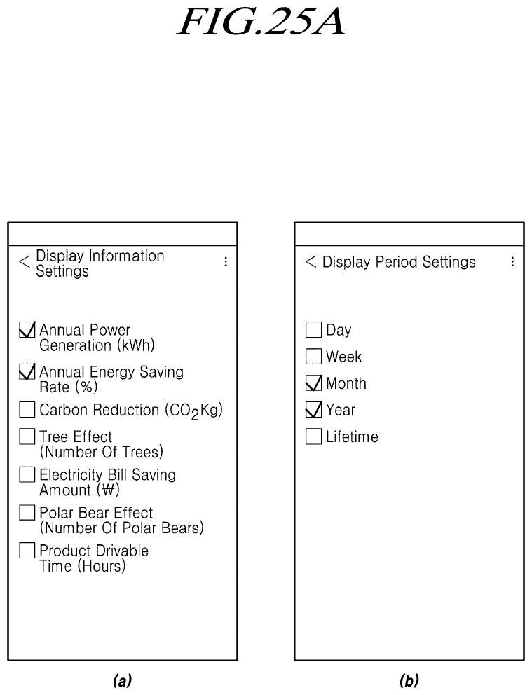

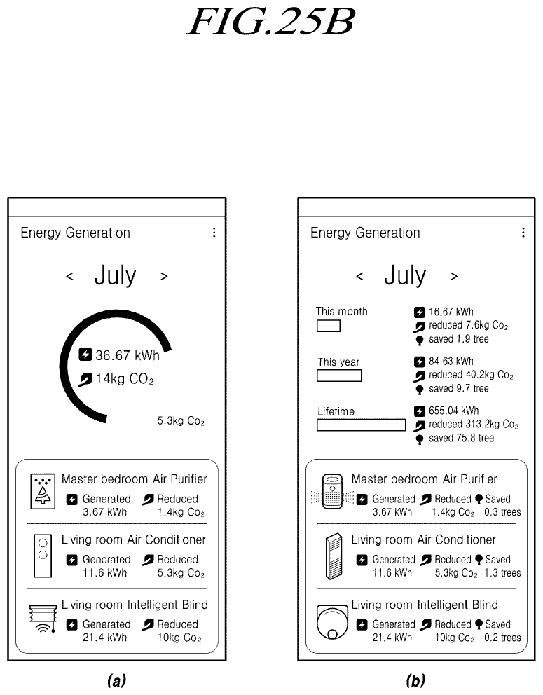

According to an embodiment, the amount of solar power generation provided through the monitoring screen may be expressed as the amount of power generation of all the placed (or installed) solar devices, or may be expressed as the amount of power generation for each device. According to an embodiment, the electronic device 101 may set display information and/or a display period for expressing the amount of solar power generation on the monitoring screen, e.g., based on a user input. An example of the screen (or user interface) provided by the electronic device 101 to set display information and/or the display period is described below with reference to FIG. 25. Part (a) of FIG. 24 illustrates a first screen (hereinafter, referred to as a first monitoring screen) for monitoring the solar power generation effect displayed by the electronic device 101.

According to an embodiment, the first monitoring screen may include monitoring information (hereinafter, referred to as first monitoring information) about the solar power generation effect at an overview level.

According to an embodiment, the first monitoring information may include power generation amount-related information (hereinafter, first power generation amount-related information) for the lookup date for all the solar devices, power generation amount-related information (hereinafter, second power generation amount-related information) for the corresponding month for all the solar devices, and/or power generation amount-related information (hereinafter, third power generation amount-related information) for the corresponding year for all the solar devices. All the solar devices may be, e.g., all of the solar devices installed (or placed).

According to an embodiment, the first power generation amount-related information of the first monitoring information may include information indicating the real-time power generation amount (cumulative power generation amount) for the lookup date for all the solar devices (e.g., the power generation amount (e.g., 2.3 kWh) from the start time of the lookup date to the lookup time point).

According to an embodiment, the second power generation amount-related information of the first monitoring information may include information indicating the real-time power generation amount (cumulative power generation amount) (e.g., power generation amount (e.g., 36.67 kWh) from the start time point of the corresponding month to the lookup time point) of the corresponding month for all the solar devices, information indicating an energy saving rate (e.g., 17.2% saving) according to the real-time power generation amount, and/or information about a graph (e.g., a bar graph) corresponding to the real-time power generation amount. The size of the graph may be proportional to the size of the real-time power generation amount of the corresponding month.

According to an embodiment, the third power generation amount-related information of the first monitoring information may include information indicating the real-time power generation amount (cumulative power generation amount) (e.g., power generation amount (e.g., 84.63 kWh) from the start time point of the corresponding year to the lookup time point) of the corresponding year for all the solar devices, information indicating the energy saving rate (e.g., 21.3% saving) according to the real-time power generation amount, and/or information about a graph (e.g., a bar graph) corresponding to the real-time power generation amount. The size of the graph may be proportional to the size of the real-time power generation amount of the corresponding year.

According to an embodiment, the first monitoring screen may further include an icon (e.g., button) for switching the first monitoring screen to the second monitoring screen. The electronic device 101 may switch the first monitoring screen to the second monitoring screen in response to receiving a user input for selecting a corresponding icon.

Part (b) of FIG. 24 illustrates a second screen (hereinafter referred to as a second monitoring screen) for monitoring the solar power generation effect displayed by the electronic device 101.

According to an embodiment, the second monitoring screen may include monitoring information (hereinafter, referred to as second monitoring information) about the solar power generation effect at a detail level.

According to an embodiment, the second monitoring information may include power generation amount-related information (hereinafter, first power generation amount-related information) for the month including the lookup date for all the solar devices, and power generation amount-related information (hereinafter, second power generation amount-related information) for the corresponding month for each solar device. All the solar devices may be, e.g., all of the solar devices installed (or placed).

According to an embodiment, the first power generation amount-related information of the second monitoring information may include information indicating the real-time power generation amount (cumulative power generation amount) (e.g., power generation amount (e.g., 36.67 kWh) from the start time point of the corresponding month to the lookup time point) of the month (e.g., July) including the lookup date for all the solar devices, information indicating an energy saving rate (e.g., 17.2% saving) according to the real-time power generation amount, and/or information about a graph (e.g., a diagram graph) corresponding to the real-time power generation amount. The size of the diagram graph may be proportional to the size of the real-time power generation amount of the corresponding month. According to an embodiment, the information indicating real-time power generation amount and the information indicating the energy saving rate may be displayed in an inner area of the diagram graph.

According to an embodiment, the second power generation information of the second monitoring information may include information indicating the real-time power generation amount (cumulative power generation amount) for the corresponding month (e.g., July) (e.g., information indicating the power generation amount from the start time point of the corresponding month to the lookup time point) and/or information indicating the energy saving rate according to the real-time power generation amount for each solar device. For example, the second power generation amount-related information of the second monitoring information may include information indicating the real-time power generation amount (e.g., 3.67 kWh) for the corresponding month (e.g., July) and information indicating the energy saving rate (e.g., 14.2% saving) according to the real-time power generation amount for the air purifier placed in the master bedroom, information indicating the real-time power generation amount (e.g., 11.6 kWh) of the corresponding month (e.g., July) and information indicating the energy saving rate (e.g., 17.8%) according to the real-time power generation amount for the air conditioner placed in the living room, and information indicating the real-time power generation amount (e.g., 21.4 kWh) of the corresponding month (e.g., July) and information indicating the energy saving rate (e.g., 22.7% saving) according to the real-time power generation amount for the smart blind (intelligent blind) placed in the living room.

According to an embodiment, the second monitoring screen may further include at least one icon (e.g., button) for switching the corresponding month to the previous or next month. The electronic device 101 may switch the corresponding month to the previous month or next month in response to receiving a user input for selecting a corresponding icon. In this case, the electronic device 101 may display the second monitoring information for the switched month.

FIG. 25A illustrates an example screen for setting information and a period to be displayed on a screen for monitoring a solar power generation effect according to an embodiment of the disclosure. FIG. 25B illustrates an example screen for monitoring a solar power generation effect displayed according to the setting of FIG. 25A according to an embodiment of the disclosure.

According to an embodiment, the electronic device (e.g., the electronic device 101 of FIG. 1/2) may display a screen (or a user interface) for setting information (hereinafter, display information) and a period (hereinafter, display period) to be displayed on a screen (e.g., the first monitoring screen of part (a) of FIG. 24 or the second monitoring screen of part (b) of FIG. 24) for monitoring the solar power generation effect.

Part (a) of FIG. 25A illustrates a screen for setting display information (hereinafter, referred to as a display information setting screen).

According to an embodiment, the display information setting screen may include a plurality of selectable display information items. For example, the display information setting screen may include an annual power generation (kWh) item, an annual energy saving rate (%) item, a carbon reduction amount (CO2 Kg) item, a tree effect (number of trees) item, an electricity bill saving amount (\) item, a polar bear effect (number of polar bears) item, and/or a product drivable time (hour) item.

According to an embodiment, the electronic device 101 may display at least one display information corresponding to at least one display information item selected by the user on the screen for monitoring the solar power generation effect through the display information setting screen.

Part (b) of FIG. 25A illustrates a screen for setting a display period (hereinafter, referred to as a display period setting screen).

According to an embodiment, the display period setting screen may include a plurality of selectable display period items. For example, the display period setting screen may include a daily item, a weekly item, a monthly item, a yearly item, and/or an all lifetime item.

According to an embodiment, the electronic device 101 may display at least one display period corresponding to at least one display period item selected by the user on the screen for monitoring the solar power generation effect through the display period setting screen.

Part (a) of FIG. 25B illustrates the screen for monitoring the solar power generation effect when the annual power generation item and carbon reduction item are selected through the display information setting screen and the monthly item is selected through the display period setting screen.

According to an embodiment, as illustrated, the monitoring screen (e.g., the second monitoring screen of the part (a) of FIG. 25B) may provide information about the annual power generation, carbon reduction amount, and related graph of the corresponding month for all the solar devices, and information about the annual power generation and carbon reduction amount of the corresponding month for each of the individual solar devices.

Part (b) of FIG. 25B illustrates the screen for monitoring the solar power generation effect when the annual power generation item, the carbon reduction item, and the tree effect item are selected through the display information setting screen, and the monthly item, the annual item, and the all lifetime item are selected through the display period setting screen.

According to an embodiment, as illustrated, the monitoring screen (e.g., the second monitoring screen of the part (b) of FIG. 25B) may provide information about the annual power generation, carbon reduction amount, tree effect, and related graph of the corresponding month, the corresponding year, and the entire cumulative period for all the solar devices, and information about the annual power generation, carbon reduction amount, and tree effect of the corresponding month, the corresponding year, and the entire cumulative period for each of the individual solar devices.

According to an embodiment, when the number of selected items (e.g., the total number of selected display information items and display period items) is equal to or larger than a defined number (e.g., n), because it is difficult to include all of the display information in the diagram graph as illustrated in part (a) of FIG. 25B, the electronic device 101 may display the corresponding display information on the screen in the form of a graph or list as illustrated in part (b) of FIG. 25B.

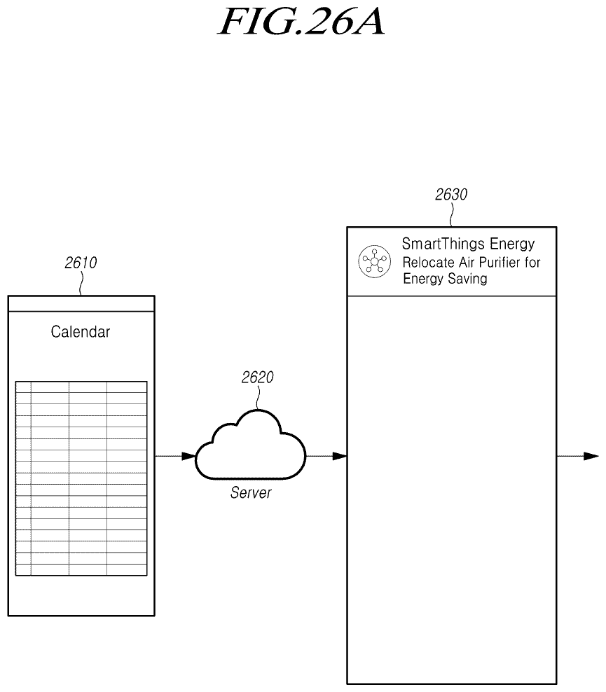

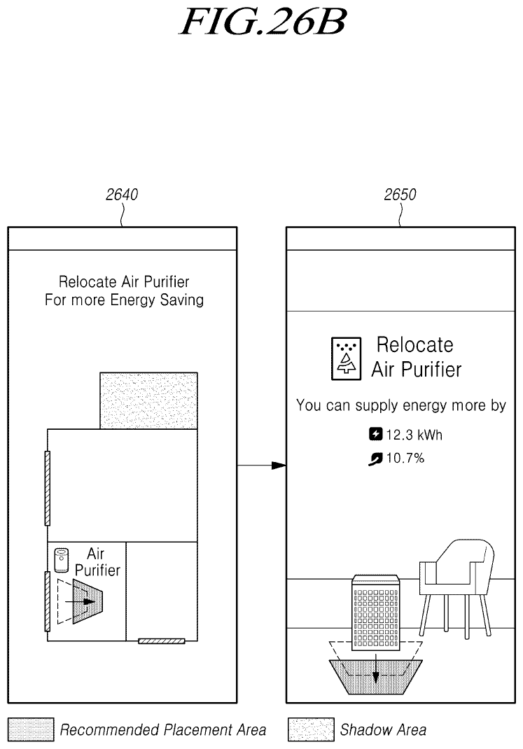

FIGS. 26A and 26B illustrate an example screen for recommending a change in a placement position of a solar device according to an embodiment of the disclosure.

Referring to FIGS. 26A and 26B, an electronic device (e.g., the electronic device 101 of FIG. 1/2) may interwork (2620) with a server (e.g., the server 200 of FIG. 2/3). For example, the information 2610 (e.g., main date information and 24-solar term information on the calendar) about the electronic device 101 may interwork (2620) with the server 200.

According to an embodiment, the server 200 may determine whether it is necessary to change the placement location (or installation location) of the solar device using the interworking information.

According to an embodiment, when it is necessary to change the placement location of the solar device, the server 200 may notify the electronic device 101 that it is necessary to change the placement location of the solar device. In this case, the electronic device 101 may display a notification indicating a change in the placement location of the corresponding solar device on the screen 2630. For example, as illustrated, the electronic device 101 may display a notification instructing to relocate the air purifier to save energy on the screen.

According to an embodiment, the electronic device 101 may display information about relocation of the corresponding solar device on the screen 2640 including a Map view (e.g., the Map view of FIG. 23B). For example, as illustrated, the electronic device 101 may display information about a product icon of the solar device (e.g., an air purifier) that needs to be relocated, an existing location (or an existing placement area), and a location to be changed to (or a placement area to be changed to) on the Map view.

According to an embodiment, the electronic device 101 may display information about relocation of the corresponding solar device on a screen 2650 including a detailed AR view (e.g., the detailed AR view of FIG. 23C). For example, as illustrated, the electronic device 101 may display information about the product icon, the product name, the 3D product image, the existing location (or the existing placement area), and/or the location to be changed to (or the placement area to be changed to) of the solar device (e.g., an air purifier) that needs to be relocated on the detailed AR view.

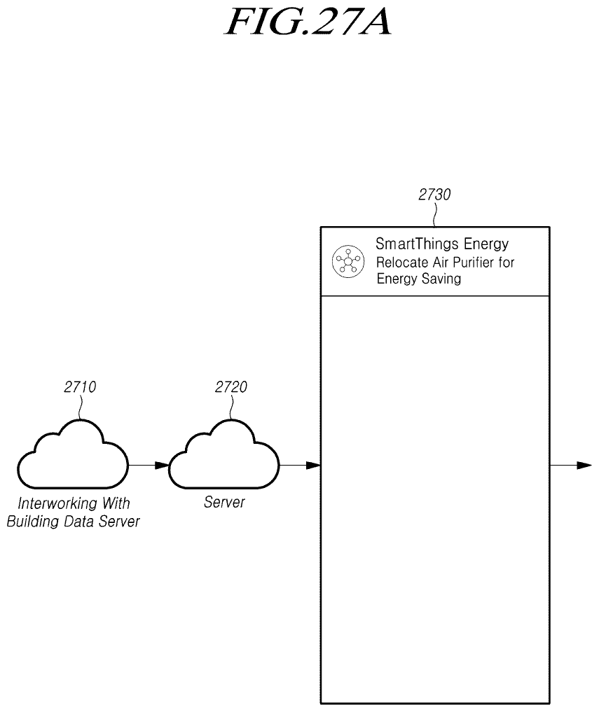

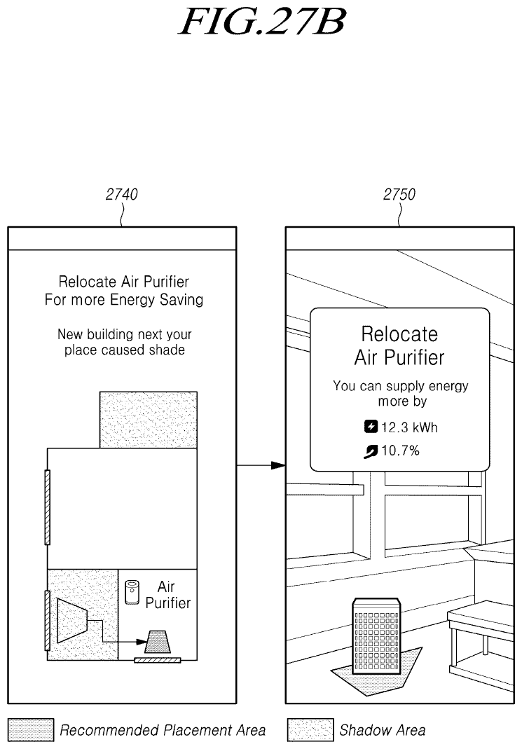

FIGS. 27A and 27B illustrate an example screen for recommending a change in a placement position of a solar device according to an embodiment of the disclosure.

Referring to FIGS. 27A and 27B, an external server (e.g., the third external server (building data server) 230 of FIG. 2) may interwork (2720) with a server (e.g., the server 200 of FIG. 2/3). For example, information 2710 (e.g., construction of a new surrounding building, etc.) related to a change in the surrounding environment in the external server may interwork (2720) with the server 200.

According to an embodiment, the server 200 may determine whether it is necessary to change the placement location (or installation location) of the solar device using the interworking information. For example, when it is identified that a shadow area is included in the whole or part of the area where the solar device is placed based on the interworking information, the server 200 may determine that the placement location of the solar device needs to be changed.

According to an embodiment, when it is necessary to change the placement location of the solar device, the server 200 may notify the electronic device 101 that it is necessary to change the placement location of the solar device. In this case, the electronic device 101 may display a notification indicating a change in the placement location of the corresponding solar device on the screen 2730. For example, as illustrated, the electronic device 101 may display a notification instructing to relocate the air purifier to save energy on the screen.

According to an embodiment, the electronic device 101 may display information about relocation of the corresponding solar device on the screen 2740 including a Map view (e.g., the Map view of FIG. 23B). For example, as illustrated, the electronic device 101 may display information about a product icon of the solar device (e.g., an air purifier) that needs to be relocated, an existing location (or an existing placement area), and a location to be changed to (or a placement area to be changed to) on the Map view. When the entire existing placement area is included in the shadow area, the electronic device 101 may shade the space including the existing placement area on the Map view.

According to an embodiment, the electronic device 101 may display information about relocation of the corresponding solar device on a screen 2750 including a detailed AR view (e.g., the detailed AR view of FIG. 23C). For example, as illustrated, the electronic device 101 may display information about the product icon, the product name, the 3D image, the existing location (or the existing placement area), and/or the location to be changed to (or the placement area to be changed to) of the solar device (e.g., an air purifier) that needs to be relocated on the detailed AR view.

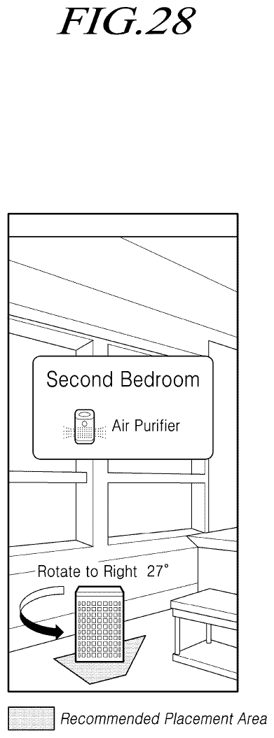

FIG. 28 illustrates an example screen showing a recommended placement angle of a solar device according to an embodiment of the disclosure.

Referring to FIG. 28, an electronic device (e.g., the electronic device 101 of FIG. 1/2) may determine a recommended placement angle (or a recommended installation angle) for the solar device. According to an embodiment, the electronic device 101 may calculate the placement angle (or the installation angle) at which annual power generation is maximum based on sunlight-related information, and may determine the placement angle at which annual power generation is maximum as the recommended placement angle.

According to an embodiment, the electronic device 101 may display information about the recommended placement angle on a detailed AR view (e.g., the detailed AR view of FIG. 23B). For example, as illustrated, the electronic device 101 may display the recommended placement angle (e.g., rotate 27 degrees to the right), the rotation direction (e.g., right direction), the recommended placement area, and/or the 3D image of the corresponding solar device on the detailed AR view.

According to an embodiment, when the angle of the corresponding solar device is adjusted (e.g., when the angle of the corresponding solar device is adjusted by the user), the electronic device 101 may display information corresponding to the adjusted angle on the detailed AR view. For example, the electronic device 101 may display information about the recommended installation angle and rotation direction changed according to the adjusted angle on the detailed AR view.

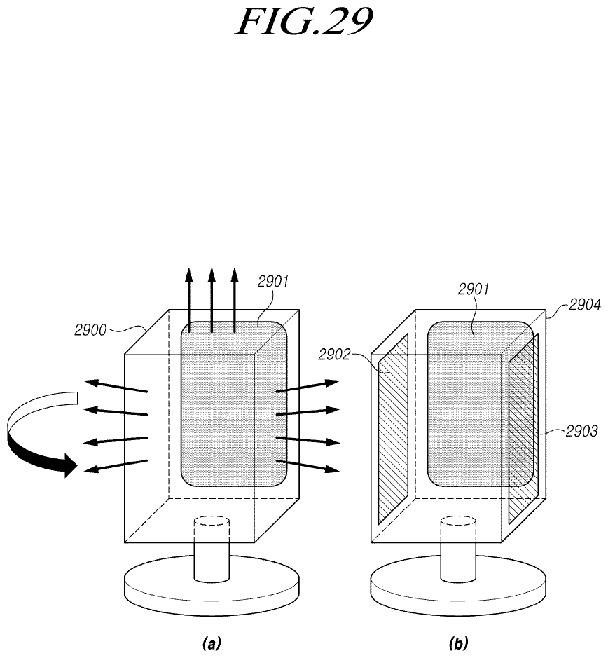

FIG. 29 is a view illustrating a method for calculating the amount of solar power generation in a rotatable solar device according to an embodiment of the disclosure.

Part (a) of FIG. 29 illustrates a rotatable solar device 2900 (e.g., an air purifier) having a solar panel 2901 attached to one surface. FIG. 29B illustrates a rotatable solar device 2900 (e.g., an air purifier) where solar panels 2901, 2902, and 2903 are attached to a plurality of surfaces (e.g., three surfaces).

According to an embodiment, the rotatable solar device 2900 may rotate by itself using, e.g., a rotary motor.

According to an embodiment, the rotatable solar device 2900 may interlock a rotation angle with a location of the sun. For example, the rotatable solar device 2900 may adjust the rotation angle according to the location of the sun so as to generate the maximum solar power generation effect (e.g., to maximize the annual power generation).

According to an embodiment, the rotatable solar device 2900 may calculate the annual solar power generation in conjunction with the rotation angle.

According to an embodiment, when the solar device 2900 includes a plurality of solar panels, the amount of power generation by the solar device 2900 may be the sum of the amounts of power generation through each solar panel.

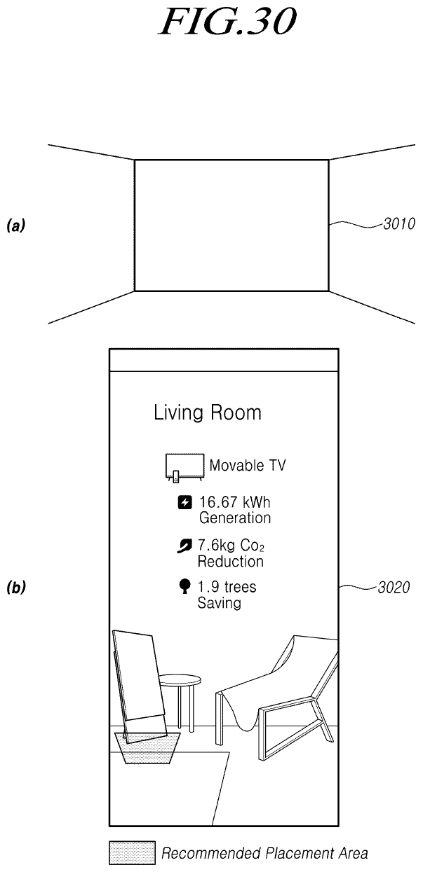

FIG. 30 illustrates a screen for displaying an optimal placement area for a space including a window having a first characteristic and information related to the amount of solar power generation according to an embodiment.

Part (a) of FIG. 30 illustrates a space (e.g., a living room) including a window 3010 having characteristic (first characteristic) placed to face south with a shape in contact with a floor.

Part (b) of FIG. 30 illustrates a screen 3020 (e.g., a detailed AR view) displaying a recommended placement area for a solar device (e.g., a mobile TV) to be placed at a first time point (e.g., summer) and/or information related to the amount of solar power generation in the space including a window 3010 having a first characteristic. As shown, when the solar device is placed in summer, it may be recommended to be placed in a central area in contact with the window.

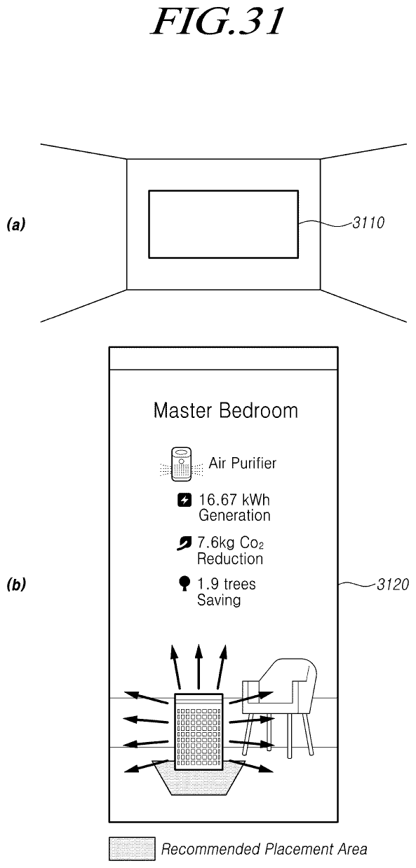

FIG. 31 illustrates an example screen displaying an optimal placement area and solar power generation amount-related information for a space including a window having a second characteristic according to an embodiment of the disclosure.

Part (a) of FIG. 31 illustrates a space (e.g., a master bedroom) including a window 3110 having a characteristic (second characteristic) of being placed facing south with a shape spaced apart from the floor.

Part (b) of FIG. 31 illustrates a screen (e.g., a detailed AR view) displaying a recommended placement area and/or solar power generation amount-related information for a solar device 3120 (e.g., an air purifier) to be placed at a first time point (e.g., summer) in the space including the window 3110 having the second characteristic. As shown, when the solar device is placed in summer, it may be recommended to be placed in a central area away from the window by a defined distance.

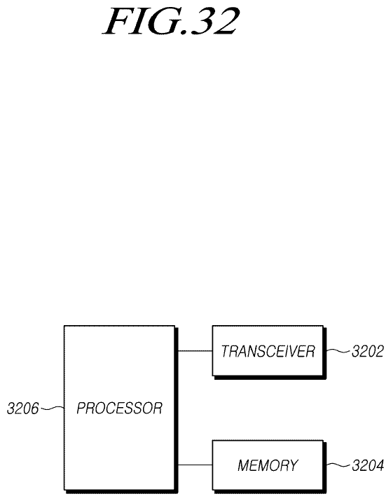

FIG. 32 is a block diagram illustrating a server according to an embodiment of the disclosure.

Referring to FIG. 32, a server (e.g., the server 200 of FIG. 2) may include a transceiver 3202, memory 3204, and a processor 3206. According to an embodiment, the server 200 may include an additional component (e.g., a communication module for communication with another server) other than the illustrated components, or may omit at least one of the illustrated components.

According to an embodiment, the transceiver 3202 may communicate with at least one client device. For example, the transceiver 3202 may communicate with at least one client device based on any of various wired or wireless communication protocols such as Ethernet, GSM, EDGE, CDMA, TDMA, LTE, LTE-A, NR, Wi-Fi, or Bluetooth.

According to an embodiment, the memory 3204 may store various information or data associated with the operation of the server 200 and may store at least one instruction (or at least one program including at least one instruction).

According to an embodiment, the processor 3206 may be electrically or operatively connected to the transceiver 3202 and the memory 3204, and may execute at least one instruction of the program stored in the memory 3204. There may be one or more processors 3206 which may perform the above-described operations of the server 200, e.g., the operations of the server 200 described with reference to FIGS. 2 to 31.

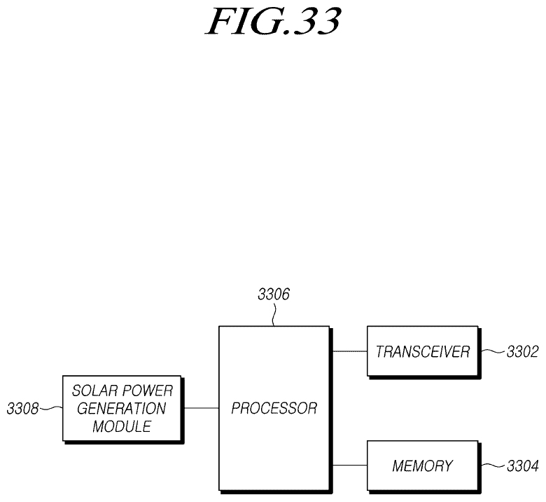

FIG. 33 is a block diagram illustrating a solar device according to an embodiment of the disclosure.

Referring to FIG. 33, a solar device (e.g., the solar device 10 of FIG. 2) may include a transceiver 3302, memory 3304, a processor 3306, and a solar power generation module 3308. According to an embodiment, the solar device 10 may include an additional component (e.g., a battery storing electricity generated by solar power generation) other than the illustrated components, or may omit at least one of the illustrated components.

According to an embodiment, the transceiver 3302 may communicate with at least one client device. For example, the transceiver 3302 may communicate with at least one client device based on any of various wired or wireless communication protocols such as Ethernet, GSM, EDGE, CDMA, TDMA, LTE, LTE-A, NR, Wi-Fi, or Bluetooth.

According to an embodiment, the memory 3304 may store various information or data associated with the operation of the solar device 10 and may store at least one instruction (or at least one program including at least one instruction).

According to an embodiment, the processor 3306 may be electrically or operatively connected to the transceiver 3302 and the memory 3304, and may execute at least one instruction of the program stored in the memory 3304. There may be one or more processors 3306 which may perform the above-described operations of the solar device 10, e.g., the operations of the solar device 10 described with reference to FIGS. 2 to 31.

According to an embodiment, the solar power generation module 3308 may include at least one solar panel for performing a solar power generation function. The solar device 10 may generate electricity using sunlight irradiated to the solar panel.

According to an embodiment, an electronic device may comprise memory storing at least one instruction, and at least one processor connected to the memory and executing at least one instruction stored in the memory.

According to an embodiment, the at least one processor of the electronic device 101 may obtain at least one information for performing a solar power generation simulation on a device having a solar power generation function. The at least one information may include window transmission loss rate-related information related to a loss rate of sunlight transmitted through a window in a space. It is possible to increase the accuracy of solar power generation simulation for the solar device placed indoors through the window transmission loss rate-related information.

According to an embodiment, the at least one processor of the electronic device 101 may transmit the at least one information including the window transmission loss rate-related information to the server.

According to an embodiment, the at least one processor of the electronic device 101 may receive result data of the solar power generation simulation from the server. The result data may include information about a recommended placement area of the solar device and information about a solar power generation effect in the recommended placement area.

According to an embodiment, the at least one processor of the electronic device 101 may display the recommended placement area and first information related to the solar power generation effect on the space or a map associated with the space, based on the result data. The information about the solar power generation effect may be obtained based on the window transmission loss rate-related information.

According to an embodiment, the window transmission loss rate-related information may include transmission loss rate information indicating the loss rate generated when the sunlight is transmitted through the window in the space or illuminance information used to calculate the loss rate generated when the sunlight is transmitted through the window in the space.

According to an embodiment, the illuminance information may include a first illuminance value obtained through an illuminance sensor in a state where the window is closed and a second illuminance value obtained through the illuminance sensor in a state where the window is open.

According to an embodiment, displaying the recommended placement area and the first information on the space may include displaying an augmented image including the recommended placement area and the first information on a real environment including the space.

According to an embodiment, the at least one processor of the electronic device 101 may be configured to display second information related to the solar power generation effect on the space based on identifying an event for displaying detailed information about the solar power generation effect while the recommended placement area and the first information related to the solar power generation effect are displayed on the space or the map related to the space.

According to an embodiment, the first information may include information indicating an annual solar power generation amount and information indicating an annual energy saving rate, and the second information may include at least one of information indicating a tree effect according to the annual solar power generation amount, information indicating a polar bear effect according to the annual solar power generation amount, information indicating a carbon reduction amount according to the annual solar power generation amount, or information indicating a cost saving amount according to the annual solar power generation amount, and information indicating the annual solar power generation amount.

According to an embodiment, the at least one information may include information related to a location of the space, information related to the space, and information related to the solar device, and the information related to the space may include three-dimensional space information obtained through 3D scanning of the space and information about a location, a size, and a direction of the window in the space.

According to an embodiment, the recommended placement area may be determined based on a common daylighting area for sunlight entering through the window at a designated time point. The common daylighting area may be determined using sunlight-related information obtained from an external server based on the information related to the space and the information related to the location of the space. The sunlight-related information may include information about a meridian altitude of the sun and information about an azimuth of the sun.

According to an embodiment, the recommended placement area may be determined based on a shadow area identified based on information related to a surrounding building obtained from an external server based on the information related to the location of the space. The obtained surrounding building-related information may include at least one information about a height of at least one building located around a building including the space, a distance to the building, a placement thereof, or a shadow thereof.

According to an embodiment, the recommended placement area may be determined based on information related to a solar device characteristic obtained from an external server based on the solar device-related information. The solar device characteristic-related information may include information about a minimum interval necessary to place or install the solar device.

According to an embodiment, the information indicating the annual solar power generation amount may be obtained based on the information related to the space, the window transmission loss rate-related information, sunlight-related information obtained from an external server based on the information related to the location of the space, and information related to a solar device characteristic obtained from the external server based on the solar device-related information. The information indicating the annual energy saving rate may be obtained based on information indicating the annual solar power generation amount and solar device characteristic-related information. The solar energy-related information may include information about annual solar irradiation, and the solar device characteristic-related information includes information about a module angle loss rate of the solar panel, a panel size, a number of panels, and panel power generation efficiency.

According to an embodiment, a server 200 may comprise memory 1404 storing at least one instruction and at least one processor 1406 connected to the memory and executing at least one instruction stored in the memory.

According to an embodiment, the at least one processor of the server 200 may receive, from an electronic device, at least one information for performing a solar power generation simulation on a solar device having a solar power generation function. The at least one information may include window transmission loss rate-related information related to a loss rate of sunlight transmitted through a window in a space.

According to an embodiment, the at least one processor of the server 200 may generate result data of the solar power generation simulation based on the at least one information. The result data may include information about a recommended placement area of the solar device and information about a solar power generation effect in the recommended placement area.

According to an embodiment, the at least one processor of the server 200 may transmit result data of the solar power generation simulation to the electronic device. The information about the solar power generation effect may be obtained based on the window transmission loss rate-related information.

According to an embodiment, the window transmission loss rate-related information may include transmission loss rate information indicating the loss rate generated when the sunlight is transmitted through the window in the space or illuminance information used to calculate the loss rate generated when the sunlight is transmitted through the window in the space. The illuminance information may include a first illuminance value obtained through an illuminance sensor in a state where the window is closed and a second illuminance value obtained through the illuminance sensor in a state where the window is open.

According to an embodiment, the at least one information may include information related to a location of the space, information related to the space, and information related to the solar device, and the information related to the space may include three-dimensional space information obtained through 3D scanning of the space and information about a location, a size, and a direction of the window in the space.

According to an embodiment, the at least one processor of the server 200 may determine a common daylighting area for sunlight entering through the window at a designated time point, using sunlight-related information obtained from an external server based on the information related to the space and the information related to the location of the space, and determine the recommended placement area based on the common daylighting area. The sunlight-related information may include information about a meridian altitude of the sun and information about an azimuth of the sun.

According to an embodiment, to determine the recommended placement area based on the common daylighting area, the at least one processor of the server 200 may identify whether a shadow area is present in the common daylighting area based on information related to a surrounding building obtained from an external server based on the information related to the location of the space; and determine the recommended placement area based on a result of the identification. The obtained surrounding building-related information may include at least one information about a height of at least one building located around a building including the space, a distance to the building, a placement thereof, or a shadow thereof.

According to an embodiment, to determine the recommended placement area based on the common daylighting area, the at least one processor of the server 200 may determine the recommended placement area in the common daylighting area, based on information related to a solar device characteristic obtained from an external server based on the solar device-related information. The solar device characteristic-related information may include information about a minimum interval necessary to place or install the solar device.

According to an embodiment, the at least one processor of the server 200 may obtain the information indicating the annual solar power generation amount based on the information related to the space, the window transmission loss rate-related information, sunlight-related information obtained from an external server based on the information related to the location of the space, and information related to a solar device characteristic obtained from the external server based on the solar device-related information, and obtain the information indicating the annual energy saving rate based on information indicating the annual solar power generation amount and solar device characteristic-related information. The solar energy-related information may include information about annual solar irradiation, and the solar device characteristic-related information may include information about a module angle loss rate of the solar panel, a panel size, a number of panels, and panel power generation efficiency.

According to an embodiment, an electronic device may comprise memory storing at least one instruction, and at least one processor connected to the memory and executing at least one instruction stored in the memory.

According to an embodiment, the at least one processor of the electronic device 101 may obtain at least one information for performing a solar power generation simulation on a solar device having a solar power generation function. The at least one information may include window transmission loss rate-related information related to a loss rate of sunlight transmitted through a window in a space.

According to an embodiment, the at least one processor of the electronic device 101 may generate result data of the solar power generation simulation based on the at least one information. The result data may include information about a recommended placement area of the solar device and information about a solar power generation effect in the recommended placement area.

According to an embodiment, the at least one processor of the electronic device 101 may display the recommended placement area and first information related to the solar power generation effect on the space or a map associated with the space, based on the result data. The information about the solar power generation effect may be obtained based on the window transmission loss rate-related information.

According to an embodiment, the window transmission loss rate-related information may include transmission loss rate information indicating the loss rate generated when the sunlight is transmitted through the window in the space or illuminance information used to calculate the loss rate generated when the sunlight is transmitted through the window in the space. The illuminance information may include a first illuminance value obtained through an illuminance sensor in a state where the window is closed and a second illuminance value obtained through the illuminance sensor in a state where the window is open.

According to an embodiment, the at least one information may include information related to a location of the space, information related to the space, and information related to the solar device, and the information related to the space may include three-dimensional space information obtained through 3D scanning of the space and information about a location, a size, and a direction of the window in the space.

According to an embodiment, the at least one processor of the electronic device 101 may determine a common daylighting area for sunlight entering through the window at a designated time point, using sunlight-related information obtained from an external server based on the information related to the space and the information related to the location of the space, and determine the recommended placement area based on the common daylighting area. The sunlight-related information may include information about a meridian altitude of the sun and information about an azimuth of the sun.

In the above-described specific embodiments, the components included in the disclosure are represented in singular or plural forms depending on specific embodiments proposed. However, the singular or plural forms are selected to be adequate for contexts suggested for ease of description, and the disclosure is not limited to singular or plural components. As used herein, the singular forms “a,” “an,” and “the” are intended to include the plural forms as well, unless the context clearly indicates otherwise.

Although specific embodiments of the disclosure have been described above, various changes may be made thereto without departing from the scope of the disclosure. Thus, the scope of the disclosure should not be limited to the above-described embodiments, and should rather be defined by the following claims and equivalents thereof.

What is claimed is:

1. An electronic device, comprising:
a memory to store at least one instruction; and
at least one processor connected to the memory and to execute the at least one instruction which is stored in the memory, wherein the at least one processor is configured to:
obtain at least one information useable to perform a solar power generation simulation relative to placement of a solar device having a solar power generation function in a space, the at least one information including window transmission loss rate-related information related to a loss rate of sunlight transmitted through a window in the space;
transmit the at least one information including the window transmission loss rate-related information to a server;
receive result data of the solar power generation simulation from the server, the result data including information about a recommended placement area of the solar device in the space and information about a solar power generation effect in the recommended placement area in the space; and
provide the recommended placement area and information related to the solar power generation effect on the space or a map associated with the space, based on the result data, and
wherein the information about the solar power generation effect is obtained based on the window transmission loss rate-related information.

2. The electronic device of claim 1, wherein the window transmission loss rate-related information includes information on the loss rate of the sunlight transmitted through the window in the space or illuminance information used to calculate the loss rate of the sunlight transmitted through the window in the space, and
wherein the illuminance information includes a first illuminance value obtained through an illuminance sensor in a state where the window is closed and a second illuminance value obtained through the illuminance sensor in a state where the window is open.

3. The electronic device of claim 1, further comprising:
a display, and
wherein providing the recommended placement area and the information related to the solar power generation effect on the space includes displaying an augmented image including the recommended placement area and the information related to the solar power generation effect on a real environment including the space.

4. The electronic device of claim 1, further comprising:
a display, and
wherein the information related to the solar power generation effect is first information, and
the at least one processor is configured to provide second information related to the solar power generation effect on the space based on identifying an event displaying detailed information about the solar power generation effect while the recommended placement area and the first information related to the solar power generation effect are displayed on the space or the map related to the space via the display.

5. The electronic device of claim 4, wherein the first information includes information indicating an annual solar power generation amount and information indicating an annual energy saving rate, and
wherein the second information includes at least one of information indicating a tree effect according to the annual solar power generation amount, information indicating a polar bear effect according to the annual solar power generation amount, information indicating a carbon reduction amount according to the annual solar power generation amount, or information indicating a cost saving amount according to the annual solar power generation amount, and information indicating the annual solar power generation amount.

6. The electronic device of claim 1, wherein the at least one information includes information related to a location of the space, information related to the space, and information related to the solar device, and
wherein the information related to the space includes three-dimensional (3D) space information obtained through 3D scanning of the space and information about a location, a size, and a direction of the window in the space.

7. The electronic device of claim 6, wherein the recommended placement area is determined based on a common daylighting area for sunlight entering through the window at a designated time point,
wherein the common daylighting area is determined using sunlight-related information obtained from an external server based on the information related to the space and the information related to the location of the space, and
wherein the sunlight-related information includes information about a meridian altitude of the sun and information about an azimuth of the sun.

8. The electronic device of claim 7, wherein the recommended placement area is determined based on a shadow area identified based on information related to a surrounding building obtained from an external server based on the information related to the location of the space, and
wherein the information related to the surrounding building obtained includes at least one of information about a height of at least one building located around a building including the space, a distance to the building, a placement thereof, or a shadow thereof.

9. The electronic device of claim 7, wherein the recommended placement area is determined based on information related to a solar device characteristic obtained from an external server based on the information related to the solar device, and
wherein the information related to the solar device characteristic obtained includes information about a minimum interval necessary to place or install the solar device.

10. The electronic device of claim 5, wherein the information indicating the annual solar power generation amount is obtained based on the information related to the space, the window transmission loss rate-related information, sunlight-related information obtained from an external server based on the information related to a location of the space, and information related to a solar device characteristic obtained from an external server based on information related to the solar device,
wherein the information indicating the annual energy saving rate is obtained based on information indicating the annual solar power generation amount and solar device characteristic-related information,
wherein the sunlight-related information includes information about annual solar irradiation, and
wherein the solar device characteristic-related information includes information about a module angle loss rate of a solar panel, a panel size, a number of panels, and panel power generation efficiency.

11. A server, comprising:
a memory to store at least one instruction; and
at least one processor connected to the memory and to execute at least one instruction stored in the memory, wherein the at least one processor is configured to:
receive, from an electronic device, at least one information useable to perform a solar power generation simulation relative to placement of a solar device having a solar power generation function in a space, the at least one information including window transmission loss rate-related information related to a loss rate of sunlight transmitted through a window in the space;
generate result data of the solar power generation simulation based on the at least one information, the result data including information about a recommended placement area of the solar device in the space and information about a solar power generation effect in the recommended placement area in the space; and
transmit the result data of the solar power generation simulation to the electronic device, and
wherein the information about the solar power generation effect is obtained based on the window transmission loss rate-related information.

12. The server of claim 11, wherein the window transmission loss rate-related information includes information on the loss rate of the sunlight transmitted through the window in the space or illuminance information used to calculate the loss rate of the sunlight transmitted through the window in the space, and
wherein the illuminance information includes a first illuminance value obtained through an illuminance sensor in a state where the window is closed and a second illuminance value obtained through the illuminance sensor in a state where the window is open.

13. The server of claim 11, wherein the at least one information includes information related to a location of the space, information related to the space, and information related to the solar device, and
wherein the information related to the space includes three-dimensional (3D) space information obtained through 3D scanning of the space and information about a location, a size, and a direction of the window in the space.

14. The server of claim 13, wherein the at least one processor is configured to:
determine a common daylighting area for sunlight entering through the window at a designated time point, using sunlight-related information obtained from an external server based on the information related to the space and the information related to the location of the space; and
determine the recommended placement area based on the common daylighting area, and
wherein the sunlight-related information includes information about a meridian altitude of the sun and information about an azimuth of the sun.

15. The server of claim 14, wherein to determine the recommended placement area based on the common daylighting area, the at least one processor is configured to:
identify whether a shadow area is present in the common daylighting area based on information related to a surrounding building obtained from an external server based on the information related to the location of the space; and
determine the recommended placement area based on whether the shadow area is identified as present, and
wherein the information related to the surrounding building obtained includes at least one of information about a height of at least one building located around a building including the space, a distance to the building, a placement thereof, or a shadow thereof.

16. The server of claim 14, wherein to determine the recommended placement area based on the common daylighting area, the at least one processor is configured to determine the recommended placement area in the common daylighting area, based on information related to a solar device characteristic obtained from an external server based on information related to the solar device, and
wherein the information related to the solar device characteristic includes information about a minimum interval necessary to place or install the solar device.

17. The server of claim 11, wherein the at least one processor is configured to:
obtain information indicating an annual solar power generation amount based on information related to the space, the window transmission loss rate-related information, sunlight-related information obtained from an external server based on the information related to a location of the space, and information related to a solar device characteristic obtained from the external server based on information related to the solar device; and
obtain information indicating an annual energy saving rate based on information indicating the annual solar power generation amount and the information related to the solar device characteristic,
wherein the sunlight-related information includes information about annual solar irradiation, and
wherein the information related to the solar device characteristic includes information about a module angle loss rate of a solar panel, a panel size, a number of panels, and panel power generation efficiency.

18. An electronic device, comprising:
a memory to store at least one instruction; and
at least one processor connected to the memory and to execute at least one instruction stored in the memory, wherein the at least one processor is configured to:
obtain at least one information useable to perform a solar power generation simulation relative to placement of a solar device having a solar power generation function in a space, the at least one information including window transmission loss rate-related information related to a loss rate of sunlight transmitted through a window in the space;
generate result data of the solar power generation simulation based on the at least one information, the result data including information about a recommended placement area of the solar device in the space and information about a solar power generation effect in the recommended placement area in the space; and
provide the recommended placement area and information related to the solar power generation effect on the space or a map associated with the space, based on the result data, and
wherein the information about the solar power generation effect is obtained based on the window transmission loss rate-related information.

19. The electronic device of claim 18, wherein the window transmission loss rate-related information includes transmission loss rate information indicating the loss rate generated when the sunlight is transmitted through the window in the space or illuminance information used to calculate the loss rate generated when the sunlight is transmitted through the window in the space, and
wherein the illuminance information includes a first illuminance value obtained through an illuminance sensor in a state where the window is closed and a second illuminance value obtained through the illuminance sensor in a state where the window is open.

20. The electronic device of claim 18, wherein the at least one information includes information related to a location of the space, information related to the space, and information related to the solar device,
wherein the information related to the space includes three-dimensional (3D) space information obtained through 3D scanning of the space and information about a location, a size, and a direction of the window in the space, and
wherein the at least one processor is configured to:
determine a common daylighting area for sunlight entering through the window at a designated time point, using sunlight-related information obtained from an external server based on the information related to the space and the information related to the location of the space; and
determine the recommended placement area based on the common daylighting area, and
wherein the sunlight-related information includes information about a meridian altitude of the sun and information about an azimuth of the sun.
